(19) United States
(12) Patent Application Publication
(10) Pub. No.: US 2022/0028884 A1
(43) Pub. Date: Jan. 27, 2022

(54) SEMICONDUCTOR STORAGE DEVICE

(71) Applicant: Kioxia Corporation, Tokyo (JP)

(72) Inventor: Ken FURUBAYASHI, Yokohama (JP)

(73) Assignee: Kioxia Corporation, Tokyo (JP)

(21) Appl. No.: 17/197,170

(22) Filed: Mar. 10, 2021

(51) Int. Cl. H01L 27/11582

(52) U.S. Cl. CPC H01L 27/11582

(57) ABSTRACT

A semiconductor storage device of an embodiment includes: a stacked body in which a plurality of first conductive layers is stacked with a first insulating layer interposed between the plurality of first conductive layers, the stacked body having a stepped region in which end portions of the plurality of first conductive layers are terminated in a stepped shape and a memory region in which a plurality of memory cells is arranged; a second insulating layer that covers the stepped region and reaches at least a height of an upper surface of the stacked body in the memory region; and a first structure having a longitudinal direction along a first direction that intersects an ascending/descending direction of the stepped region, the first structure extending in a stacking direction of the stacked body in the second insulating layer, the first structure interrupting spread of the second insulating layer on the stepped region in a second direction along the ascending/descending direction.

### CROSS-REFERENCE TO RELATED APPLICATIONS

This application is based upon and claims the benefit of priority from Japanese Patent Application No. 2020-126758, filed on Jul. 27, 2020; the entire contents of which are incorporated herein by reference.

### FIELD

Embodiments of the present invention described herein relate generally to a semiconductor storage device.

### BACKGROUND

In a three-dimensional nonvolatile memory, memory cells are three-dimensionally arranged with respect to a plurality of stacked conductive layers. In such a configuration, it is desirable to mitigate the stress caused by a difference in material between the stacked body and the peripheral portion thereof.

### BRIEF DESCRIPTION OF THE DRAWINGS

FIGS. 1A to 1F are schematic views illustrating configuration examples of a semiconductor storage device according to a first embodiment;

FIGS. 2Aa to 2Bb are views illustrating examples of a procedure of a method for manufacturing the semiconductor storage device according to the first embodiment;

FIGS. 3Aa to 3Bb are views illustrating examples of the procedure of the method for manufacturing the semiconductor storage device according to the first embodiment;

FIGS. 4Aa to 4Bb are views illustrating examples of the procedure of the method for manufacturing the semiconductor storage device according to the first embodiment;

FIGS. 5Aa to 5Bb are views illustrating examples of the procedure of the method for manufacturing the semiconductor storage device according to the first embodiment;

FIGS. 6Aa to 6Bb are views illustrating examples of the procedure of the method for manufacturing the semiconductor storage device according to the first embodiment;

FIGS. 7Aa to 7Bb are views illustrating examples of the procedure of the method for manufacturing the semiconductor storage device according to the first embodiment;

FIGS. 7Ca and 7Cb are views illustrating examples of a plurality of split bands of a semiconductor storage device according to a first modification of the first embodiment;

FIGS. 7Da and 7Db are views illustrating examples of a plurality of split bands of a semiconductor storage device according to a second modification of the first embodiment;

FIGS. 8A to 8C are schematic views illustrating configuration examples of a semiconductor storage device according to a second embodiment;

FIGS. 9Aa to 9Bb are views illustrating examples of a procedure of a method for manufacturing the semiconductor storage device according to the second embodiment;

FIGS. 10Aa to 10Bb are views illustrating examples of the procedure of the method for manufacturing the semiconductor storage device according to the second embodiment;

FIGS. 11Aa to 11Bb are views illustrating examples of the procedure of the method for manufacturing the semiconductor storage device according to the second embodiment;

FIGS. 12Aa to 12Bb are views illustrating examples of the procedure of the method for manufacturing the semiconductor storage device according to the second embodiment;

FIGS. 13Aa to 13Bb are views illustrating examples of the procedure of the method for manufacturing the semiconductor storage device according to the second embodiment;

FIGS. 14Aa to 14Bb are views illustrating examples of the procedure of the method for manufacturing the semiconductor storage device according to the second embodiment;

FIGS. 15Aa to 15Ab are views illustrating examples of the procedure of the method for manufacturing the semiconductor storage device according to the second embodiment;

FIGS. 16A to 16C are schematic views illustrating configuration examples of semiconductor storage devices according to a third embodiment;

FIG. 17 is a cross-sectional view taken along the X direction illustrating a configuration example of a semiconductor storage device according to a fourth embodiment;

FIGS. 18Aa to 18Bb are views illustrating examples of a procedure of a method for manufacturing the semiconductor storage device according to the fourth embodiment;

FIGS. 19Aa to 19Bb are views illustrating examples of the procedure of the method for manufacturing the semiconductor storage device according to the fourth embodiment;

FIGS. 20Aa to 20Bb are views illustrating examples of the procedure of the method for manufacturing the semiconductor storage device according to the fourth embodiment; and

FIGS. 21Aa to 21Bb are views illustrating examples of the procedure of the method for manufacturing the semiconductor storage device according to the fourth embodiment.

### DETAILED DESCRIPTION

A semiconductor storage device of an embodiment includes: a stacked body in which a plurality of first conductive layers is stacked with a first insulating layer interposed between the plurality of first conductive layers, the stacked body having a stepped region in which end portions of the plurality of first conductive layers are terminated in a stepped shape and a memory region in which a plurality of memory cells is arranged; a second insulating layer that covers the stepped region and reaches at least a height of an upper surface of the stacked body in the memory region; and a first structure having a longitudinal direction along a first direction that intersects an ascending/descending direction of the stepped region, the first structure extending in a stacking direction of the stacked body in the second insulating layer, the first structure interrupting spread of the second insulating layer on the stepped region in a second direction along the ascending/descending direction.

Hereinafter, the present invention will be described in detail with reference to the drawings. Incidentally, the present invention is not limited to the following embodiments. In addition, constituent elements in the following embodiments include those that can be easily assumed by those skilled in the art or those that are substantially the same.

### First Embodiment

Hereinafter, a first embodiment will be described in detail with reference to the drawings.

(Configuration Example of Semiconductor Storage Device)

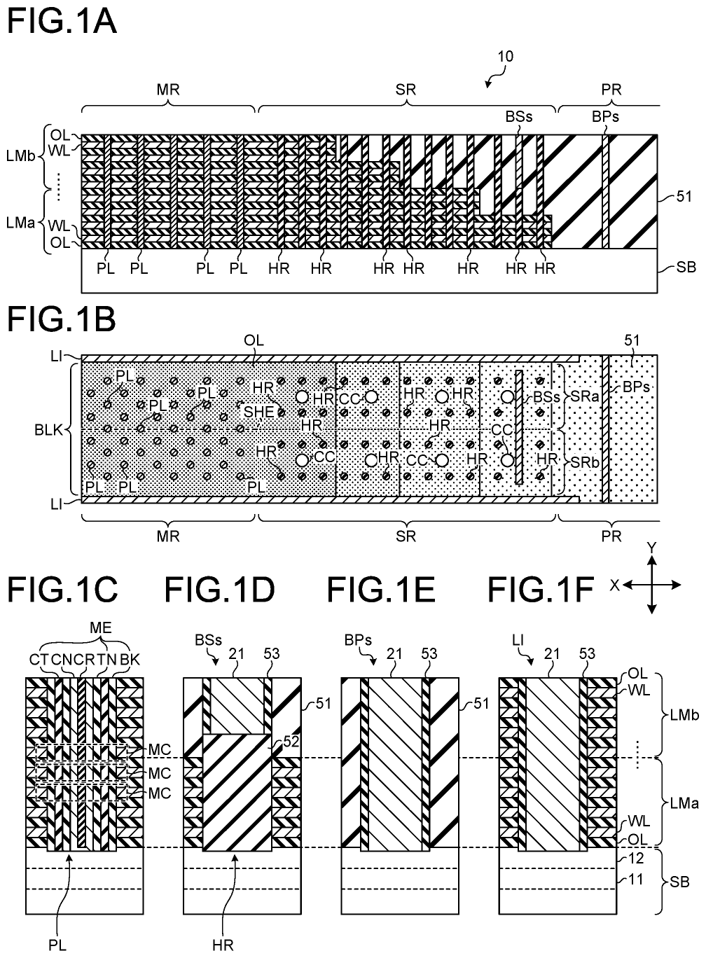

FIGS. 1A to 1F are schematic views illustrating configuration examples of a semiconductor storage device 10 according to the first embodiment. FIG. 1A is a cross-sectional view of the semiconductor storage device 10 taken along the X direction, FIG. 1B is a plan view of the semiconductor storage device 10, FIG. 1C is an enlarged cross-sectional view of a pillar PL of the semiconductor storage device 10 taken along the X direction, FIG. 1D is an enlarged cross-sectional view of a split band BSs of the semiconductor storage device 10 taken along the X direction, FIG. 1E is an enlarged cross-sectional view of a split band BPs of the semiconductor storage device 10 taken along the X direction, and FIG. 1F is an enlarged cross-sectional view of a contact LI of the semiconductor storage device 10 taken along the Y direction. However, an upper layer wiring or the like of the pillar PL and the contacts CC and LI is omitted in FIGS. 1A to 1F.

As illustrated in FIGS. 1A to 1F, the semiconductor storage device 10 includes a stacked body LMa in which a plurality of word lines WL as first conductive layers and a plurality of insulating layers OL as first insulating layers are alternately stacked, on a substrate SB such as a silicon substrate. In addition, the semiconductor storage device 10 includes a stacked body LMb in which a plurality of word lines WL as first conductive layers and a plurality of insulating layer OL as first insulating layers are alternately stacked, on the stacked body LMa. The word line WL is, for example, a tungsten layer or a molybdenum layer. The insulating layer OL is, for example, a SiO, layer or the like.

Incidentally, each of the stacked bodies LMa and LMb has the four word lines WL in the example of FIGS. 1A to 1F, but the number of the word lines WL is arbitrary. In addition, the stacked body LMa may be configured by disposing a select gate line (not illustrated) below the word line WL of the lowermost layer, or the stacked body LMb may be configured by disposing a select gate line (not illustrated) above the word line WL of the uppermost layer.

The stacked bodies LMa and LMb have a memory region MR in which a plurality of memory cells MC is arranged three-dimensionally, near centers of the stacked bodies LMa and LMb. The stacked bodies LMa and LMb have a stepped region SR in which the word lines WL are terminated in a stepped shape to individually led out the word lines WL on different layers, near ends of the stacked bodies LMa and LMb in the X direction. Incidentally, a direction in which terrace surfaces of the respective steps of the stepped region SR face is defined as an upward direction in the present specification.

The outside of the stepped region SR in the X direction, that is, the opposite side of the memory region MR, is a peripheral region PR in which an insulating layer 51 as a second insulating layer, such as a SiO₂ layer, is thickly deposited. The insulating layer 51 spreads to the peripheral region PR while covering the stepped region SR, and reaches the height of an upper surface of the stacked body LMb in the memory region MR, for example.

In the peripheral region PR, for example, a peripheral circuit (not illustrated) that contributes to the operation of the memory cell MC is arranged. The peripheral circuit includes, for example, a transistor (not illustrated) arranged on the substrate SB.

The stacked bodies LMa and LMb are divided in the Y direction by the contact LI as a split portion extending in the X direction. That is, the contact LI has a longitudinal direction along the X direction. The contact LI partitions the memory region MR and the stepped region SR into a plurality of regions called blocks BLK.

In the stacked bodies LMa and LMb of the memory region MR, an insulating member SHE indicated by the broken line extends in a band shape in the X direction. The insulating member SHE is arranged alternately with the contact LI in the Y directions, and partitions a conductive layer above the word line WL on the uppermost layer in a pattern of select gate lines (not illustrated), for example.

The split band BSs, which is first structure extending in the Y direction and interrupting the spread of the insulating layer 51 on the stepped region SR in the X direction, is arranged above the stepped region SR sandwiched between the two contacts LI. That is, the split band BSs has a longitudinal direction along the Y direction. However, the split band BSs does not completely penetrate the insulating layer 51, and bottom surface of the split band BSs is not in contact with the stacked bodies LMa and LMb in the stepped region SR. That is, lower end of the split band BSs is located above the upper surfaces of the stacked bodies LMa and LMb in the stepped region SR.

At least one split band BSs can be arranged in the stepped region SR. The plurality of split bands BSs may be arranged in the stepped region SR. In such a case, the plurality of split bands BSs may be arranged at substantially equal intervals, for example. The interval between the plurality of split bands BSs can be set to, for example, 140 μm or less.

The split band BSs has an insulating layer 53 that covers a side wall of the split band BSs. For example, a filling layer 21 filled with a material having tensile stress or the like is arranged inside the insulating layer 53. The insulating layer 53 is, for example, a SiO₂ layer or the like. The filling layer 21 is, for example, a tungsten layer or the like.

Incidentally, a metal element-containing block layer (not illustrated) may be interposed between an end surface of the insulating layer 51 facing the split band BSs and the insulating layer 53. The metal element-containing block layer is, for example, an Al₂O₃ layer or the like.

The split band BPs, which extends in the Y direction and penetrates the insulating layer 51 to reach the substrate SB, is arranged outside the stepped region SR near a terminal end portion of the contact LI in the X direction. That is, the split band BPs as a second structure has a longitudinal direction along the Y direction, and is arranged in a region of the insulating layer 51 spreading to the peripheral region PR outside the stepped region SR. The split band BPs interrupts the spread of the insulating layer 51 in the X direction. In addition, the width of the split band BPs in the X direction is wider than, for example, the width of the split band BSs in the X direction although simplified as illustrated in FIGS. 1A and 1B.

The split band BPs has an internal configuration similar to, for example, the split band BSs. That is, the split band BPs has the insulating layer 53, such as a SiO₂ layer, covering a side wall of the split band BPs, which is similar to the insulating layer 53 described above. The filling layer 21 filled with a material having tensile stress, such as tungsten, is arranged inside the insulating layer 53, which is similar to the filling layer 21 described above.

Incidentally, a metal element-containing block layer, such as an Al₂O₃ layer, may be interposed between the end surface of the insulating layer 51 facing the split band BPs and the insulating layer 53 of the split band BPs similar to the case of the split band BSs.

The contact LI penetrates the stacked bodies LMa and LMb to reach the substrate SB. The width of the contact LI in the Y direction is wider than, for example, the width of the split band BSs in the X direction.

The contact LI has an internal configuration similar to, for example, the split band BSs. That is, the contact LI has the insulating layer 53, such as a SiO₂ layer, covering a side wall of the contact LI, which is similar to the insulating layer 53 described above. The filling layer 21 filled with tungsten or the like, which is the same material as the filling layer 21, is arranged inside the insulating layer 53.

Incidentally, in the stepped region SR and an outer region of the stepped region SR, a metal element-containing block layer, such as an Al₂O₃ layer, may be interposed between the end surface of the insulating layer 51 facing the contact LI and the insulating layer 53 of the contact LI similar to the case of the split bands BSs. In addition, a metal element-containing block layer, such as an Al₂O₃ layer, may be interposed between an end portion of the insulating layer OL facing the contact LI and the insulating layer 53 of the contact LI in the contact LI inside the memory region MR.

The filling layer 21 arranged inside the contact LI has, for example, conductivity as described above and is connected to an upper layer wiring (not illustrated). As the contact LI having the conductive filling layer 21 connected to the upper layer wiring is arranged on the substrate SB, the contact LI functions as, for example, a source line contact.

In the memory region MR, a plurality of pillars PL which penetrate the stacked bodies LMa and LMb to reach the substrate SB are arranged in a matrix.

Each of the pillars PL has a memory layer ME, a channel layer CN, and a core layer CR in this order from the outer peripheral side. The channel layer CN is also arranged at a bottom of the pillar PL. The memory layer ME is, for example, a layer in which a block insulating layer BK, a charge storage layer CT, and a tunnel insulating layer TN are stacked in this order from the outer peripheral side of the pillar PL.

The channel layer CN is, for example, an amorphous silicon layer or a polysilicon layer. The core layer CR, the block insulating layer BK, and the tunnel insulating layer TN are, for example, SiO₂ layers or the like. The charge storage layer CT is, for example, a SiN layer or the like.

The substrate SB at the bottom of the pillar PL has, for example, an n-well 11 on a surface layer and a p-well 12 in the n-well 11. The p-well 12 of the substrate SB is connected to the channel layer CN at the bottom of the pillar PL.

In addition, the channel layer CN of the pillar PL is also connected to an upper layer wiring such as a bit line (not illustrated). Each of the pillars PL has the memory layer ME in which the charge storage layer CT is surrounded by the tunnel insulating layer TN and the block insulating layer BK, and the channel layer CN connected to the bit line or the like, so that the plurality of memory cells MC is formed respectively at intersections between the pillars PL and the word lines WL.

The above-described insulating member SHE is formed so as to intersect the pillars PL, for example, in upper portions of the pillars PL at the center among the pillars PL between the contacts LI arranged in the Y direction. As a result, the insulating member SHE splits a conductive layer (not illustrated) arranged above the word line WL on the uppermost layer of the stacked bodies LMa and LMb into two select gate lines adjacent to each other in the Y direction between the two contacts LI.

As described above, the plurality of memory cells MC is arranged three-dimensionally in the memory region MR, and the semiconductor storage device 10 is configured as, for example, a three-dimensional nonvolatile memory.

The stepped region SR has stepped regions SRa and SRb which are adjacent to the memory region MR in the X direction and have a plurality of rows of stepped shaped structures ascending toward the memory region MR. In the stepped region SRa, the word lines WL corresponding to odd-numbered layers, for example, the first layer, the third layer, and the fifth layer from the word line WL on the lowest layer, are led. In the stepped region SRb, the word lines WL corresponding to even-numbered layers, for example, the second layer, the fourth layer, and the sixth layer from the word line WL on the lowest layer, are led. However, the stepped shaped rows provided in the stepped region SR may be one row or three or more rows.

In the stepped region SR, a plurality of columnar bodies HR that penetrate the insulating layer 51 covering the top of the stepped region SR and the stacked bodies LMa and LMb and reach the substrate SB are arranged in a matrix. However, when the columnar bodies HR are arranged so as to overlap the position of the split band BSs, upper portions of the columnar bodies HR disappear due to the split band BSs. Further, lower portions of these columnar bodies HR penetrate the insulating layer 51 and the stacked bodies LMa and LMb in the stepped region SR from bottom surface of the split band BSs arranged in the insulating layer 51 above the stepped region SR and reach the substrate SB. However, the columnar body HR is not necessarily arranged below the split band BSs.

Each of the columnar bodies HR has a size approximately equal to, for example, the pillar PL. Each of the columnar bodies HR is filled with the insulating layer 52 such as a SiO₂ layer. The columnar body HR supports a stacked structure provided in the semiconductor storage device 10 in the middle of manufacturing during a manufacturing process of the semiconductor storage device 10 which will be described later. Therefore, it is preferable that as many columnar bodies HR as possible be arranged as densely as possible.

The plurality of contacts CC is arranged in each step of the stepped region SR. Each of the contacts CC extends from an upper surface of the insulating layer 51 to the stepped region SR below, penetrates the insulating layer OL constituting a terrace surface of a step on which the contact CC is arranged, and reaches the word line WL below the insulating layer OL. As a result, the plurality of contacts CC is electrically connected to the word lines WL on different layers.

(Method for Manufacturing Semiconductor Storage Device)

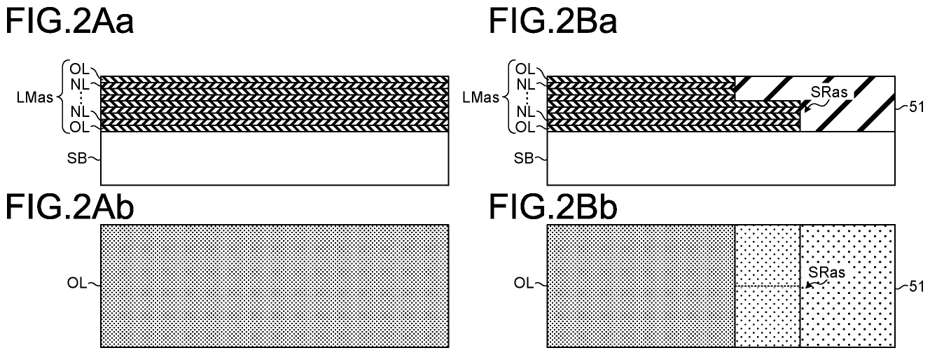

Next, an example of a method for manufacturing the semiconductor storage device 10 according to the first embodiment will be described with reference to FIGS. 2Aa to 7Bb.

FIGS. 2Aa to 7Bb are views illustrating examples of a procedure of a method for manufacturing the semiconductor storage device 10 according to the first embodiment. In the same drawing numbers A and B of FIGS. 2Aa to 7Bb, a and b indicated by lowercase letters represent a cross section and a plane, respectively, during the same processing process. The lowercase letter a in FIGS. 2Aa to 7Bb corresponds to the cross section of FIG. 1A, and the lowercase letter b corresponds to the plane of FIG. 1B.

As illustrated in FIGS. 2Aa and 2Ab, a stacked body LMas in which a plurality of sacrificial layers NL and insulating layers OL are alternately stacked is formed on the substrate SB. The sacrificial layer NL is an insulating layer such as a SiN layer, for example, and is a layer that is to be replaced with a conductive material later to form the word line WL.

As illustrated in FIGS. 2Ba and 2Bb, a stepped region SRas is formed in the stacked body LMas. The stepped region SRas corresponds to a lower layer part of the stepped region SR to be formed later.

The stepped region SRas can be formed, for example, by slimming a resist film or the like. That is, the stepped region SRas is formed by sequentially removing a predetermined number of both sacrificial layers NL and insulating layers OL from an upper layer of the stacked body LMas while slimming the resist film or the like formed on the stacked body LMas with O₂ plasma or the like.

After the stepped region SRas is formed, the stepped region SRas is covered with the insulating layer 51, for example, up to the height of an upper surface of the stacked body LMas in an unprocessed part.

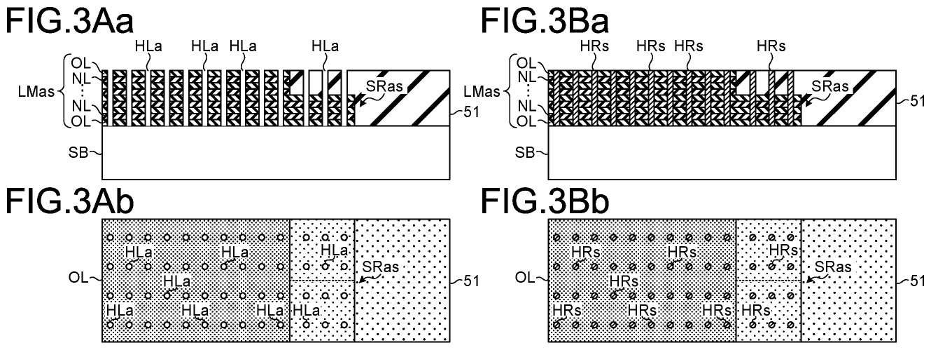

As illustrated in FIGS. 3Aa and 3Ab, a plurality of holes HLa is formed near an end portion of the stacked body LMas including the stepped region SRas. That is, the plurality of holes HLa is formed in regions near the end portion of the stacked body LMas in a region where the stepped region SRas, which is the lower layer part of the stepped region SR, is arranged and a region of the insulating layer 51 covering the stepped region SRas.

As illustrated in FIGS. 3Ba and 3Bb, the individual holes HLa are filled with sacrificial layers to form a plurality of columnar bodies HRs. The sacrificial layer is a layer that can be replaced with an insulating material to serve as a filler for the columnar body HR later, and is, for example, an amorphous silicon layer.

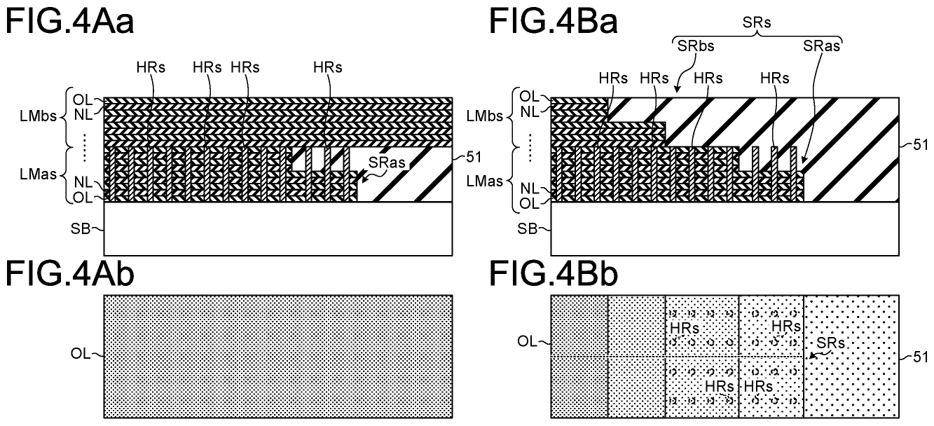

As illustrated in FIGS. 4Aa and 4Ab, a stacked body LMbs in which a plurality of sacrificial layers NL and insulating layers OL are alternately stacked is formed on the upper surface of the stacked body LMas and the upper surface of the insulating layer 51.

As illustrated in FIGS. 4Ba and 4Bb, a stepped region SRbs, which is an upper layer part of the stepped region SR to be formed later, is formed in the stacked body LMbs. The stepped region SRbs can also be formed by, for example, slimming a resist film similarly to the stepped region SRas.

As a result, a stepped region SRs, which includes the stepped region SRas and SRbs and is to serve as the stepped region SR later, is formed. In addition, the insulating layer 51 is stacked to be added to the entire stepped region SRs and a region outside the stepped region SRs so as to have the height substantially equal to, for example, the height of an upper surface of the stacked body LMbs in an unprocessed part. Such a thick insulating layer 51 causes, for example, compressive stress, and the stacked bodies LMas and LMb receive, for example, an inward external force.

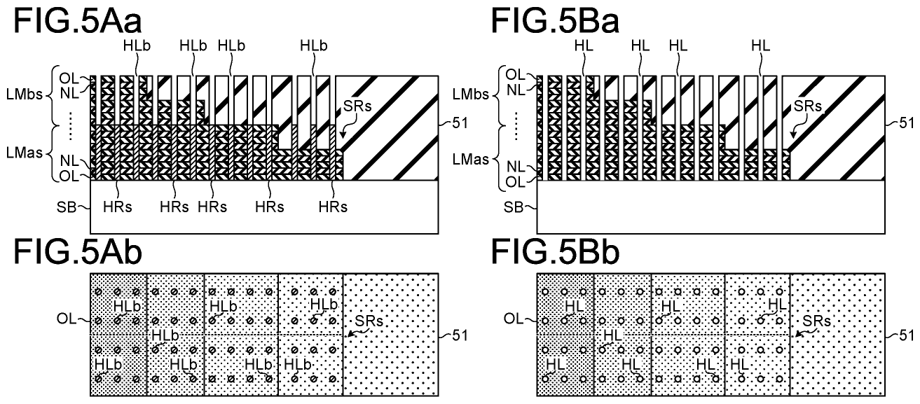

As illustrated in FIGS. 5Aa and 5Ab, a plurality of holes HLb, which reach a height position of the upper surface of the stacked body LMas in contact with a bottom surface of the stacked body LMbs from the upper surface of the stacked body LMbs in the unprocessed part or the upper surface of the insulating layer 51 covering the stepped region SRs, is formed above the individual columnar bodies HRs.

As a result, among the plurality of holes HLb, some of the holes HLb penetrate the stacked body LMbs in the stepped region SRs to be connected to the lower columnar bodies HRs. In addition, some of the holes HLb penetrate the insulating layer 51 on the stepped region SRs and the stacked body LMbs to be connected to the lower columnar bodies HRs. In addition, some of the holes HLb penetrate the insulating layer 51 on the stepped region SRs to be connected to the lower columnar bodies HRs.

As illustrated in FIGS. 5Ba and 5Bb, sacrificial layers, such as amorphous silicon layers, filling the columnar bodies HRs are removed through the holes HLb connected to upper ends of the individual columnar bodies HRs. As a result, a plurality of holes HL reaching the substrate SB from the height position of the upper surface of the stacked body LMbs in the unprocessed part is formed.

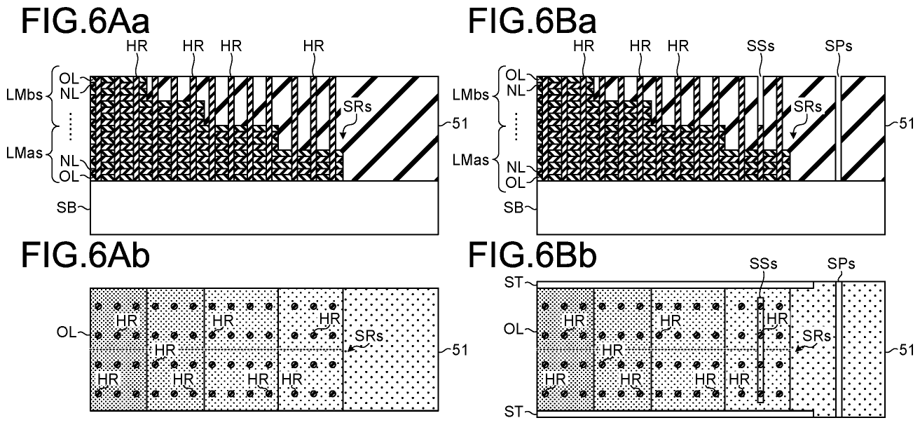

As illustrated in FIGS. 6Aa and 6Ab, the holes HL are filled with the insulating layers 52 (see FIG. 1D), such as SiO₂ layers, to form the plurality of columnar bodies HR reaching the substrate SB from the height position of the upper surface of the stacked body LMbs in the unprocessed part.

Incidentally, the plurality of pillars PL is formed in the memory region MR through the above processing. The pillar PL can be formed, for example, by a procedure similar to that of the columnar body HR.

That is, a plurality of memory holes penetrating the stacked body LMas formed on the substrate SB is formed, and the memory holes are filled with the sacrificial layers, such as amorphous silicon layers, to form lower pillars. The above processing can be carried out in parallel with, for example, the process of forming the columnar bodies HRs, that is, the processing illustrated in FIGS. 3Aa to 3Bb.

In addition, after forming the plurality of memory holes which penetrate the stacked body LMbs formed on the stacked body LMas and are connected to the individual lower pillars and removing the sacrificial layers of the lower pillars through these memory holes, the memory layer ME, the channel layer CN, and the core layer CR are formed in this order from the side wall of the memory hole in each of the memory holes penetrating the entire stacked bodies LMas and LMbs. At this time, the channel layer CN is also formed at a bottom of the memory hole where the substrate SB is exposed.

In the above processing, the formation of the memory holes and the removal of the sacrificial layers in the lower pillars can be carried out in parallel with, for example, the formation of the holes HL and the removal of the sacrificial layers in the columnar bodies HRs, that is, the processing illustrated in FIGS. 5Aa to 5Bb. In addition, the formation of the pillars PL can be carried out, for example, before the process of forming the columnar bodies HR, that is, before the processing illustrated in FIGS. 6Aa and 6Ab. Alternatively, the formation of the pillars PL can be carried out, for example, after the process of forming the columnar bodies HR, that is, after the processing illustrated in FIGS. 6Aa and 6Ab.

As described above, the plurality of pillars PL, which penetrate the stacked bodies LMas and LMbs and are connected to the substrate SB, is formed.

As illustrated in FIGS. 6Ba and 6Bb, slits ST, SSs, and SPs are formed, for example, collectively. The slit ST is a portion which is to serve as the contact LI later, and extends in the X direction. The slit SSs is a portion which is to serve as the split band BSs later, and extends in the Y direction. The slit SPs is a portion which is to serve as the split band BPs later, and extends in the Y direction. At least one or a plurality of slits SSs may be formed in the stepped region SRs.

These slits ST, SSs, and SPs are formed by, for example, a dry etching process. At this time, the slit ST penetrates the stacked bodies LMas and LMbs to reach the substrate SB. The slit SPs penetrates the insulating layer 51 to reach the substrate SB. The slit SSs extends downward in the insulating layer 51. When the columnar body HR is arranged so as to overlap the position of the slit SSs, an upper portion of this columnar body HR disappears due to the formation of the slit SSs.

Here, the width of the slit SSs in the X direction is narrower than, for example, the width of the slit SPs in the X direction and the width of the slit ST in the Y direction. In addition, an aspect ratio of the slit SSs is higher than an aspect ratio of the slits SPs and ST.

Therefore, when these slits ST, SSs, and SPs are collectively formed, an etching rate of the slit SSs is suppressed as compared with the slits ST and SPs. Therefore, when bottoms of the slits ST and SPs reach the substrate SB and the etching process of the slits ST and SPs is completed, the etching process of the slit SSs is completed without a bottom of the slit SSs reaching a terrace surface in a predetermined step of the stepped region SRs.

As the slit SPs is formed outside the stepped region SRs in this manner, the slit SPs separates the insulating layer 51 outside the stepped region SRs from the stacked bodies LMas and LMbs including the stepped region SRs. As a result, the compressive stress from the insulating layer 51 to the stacked bodies LMas and LMbs is mitigated.

Meanwhile, as the slit SPs is formed outside the stepped region SRs, for example, stress is generated in the stacked bodies LMas and LMbs to expand toward the slit SPs. The slit SSs formed above the stepped region SRs absorbs and mitigates the stress on the stacked bodies LMas and LMbs toward the slit SPs. As a result, for example, the columnar body HR formed in the stepped region SRs is suppressed from being inclined toward the outer side of the stacked bodies LMas and LMbs.

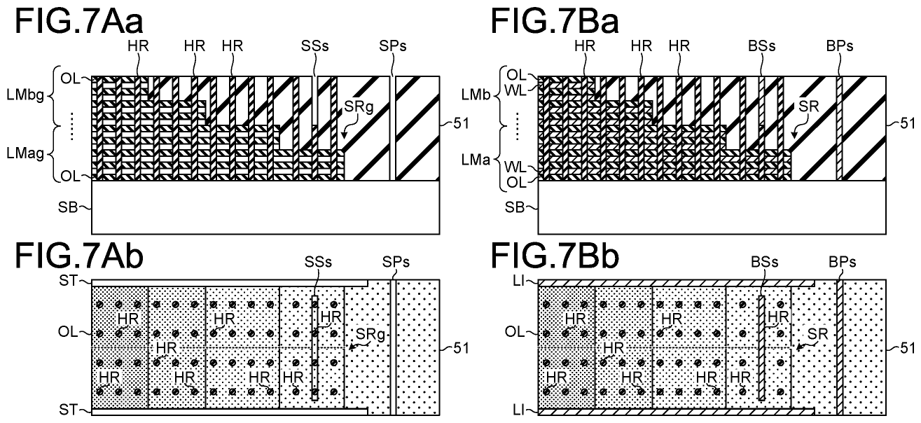

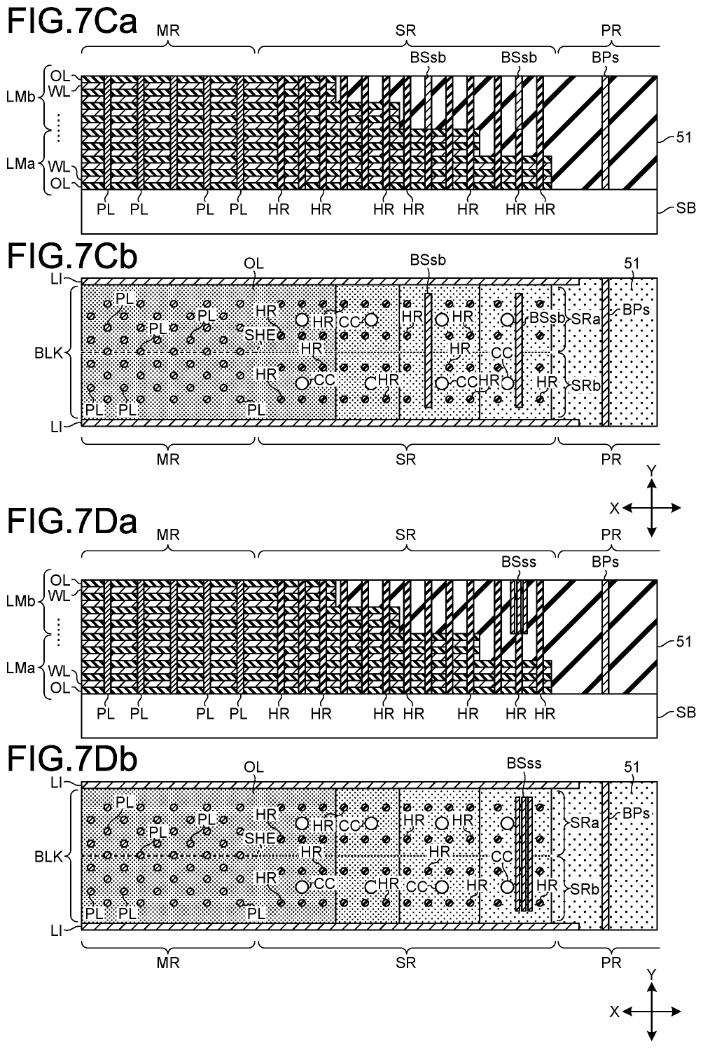

As illustrated in FIGS. 7Aa and 7Ab, the sacrificial layer NL in the stacked bodies LMas and LMbs is removed through the slit ST that divides the stacked bodies LMas and LMbs. As a result, stacked bodies LMag and LMbg having a gap between the respective insulating layers OL are formed.

At this time, the columnar body HR supports a fragile stepped region SRg having a gap. In addition, the pillar PL of the memory region MR (see FIGS. 1A and 1B) supports the fragile stacked bodies LMas and LMbs.

However, the thick insulating layer 51 formed up to the height of the upper surface of the stacked body LMbg, for example, exists above and outside the stepped region SRg of the stacked bodies LMag and LMbg as described above. The stacked bodies LMag and LMbg receive the compressive stress from the insulating layer 51, that is, an external force that crushes the stacked bodies LMag and LMbg toward the inner side.

Here, the slit SPs is formed outside the stepped region SRg and divides the insulating layer 51 on the stepped region SRg and the insulating layer 51 outside the stepped region SRg. Therefore, the compressive stress from the insulating layer 51 outside the stepped region SRg to the stacked bodies LMag and LMbg is suppressed.

In addition, the slit SSs is formed above the stepped region SRg, and the insulating layer 51 on the stepped region SRg is divided into a plurality of blocks having a predetermined size. Therefore, the compressive stress from the insulating layer 51 on the stepped region SRg to the stepped region SRg is suppressed. In addition, the stress that expands the stacked bodies LMag and LMbg toward the slit SPs is suppressed. Accordingly, the flexure of the insulating layers OL of the stacked bodies LMag and LMbg and the inclination of the columnar bodies HR toward the stacked bodies LMag and LMbg or the opposite side are suppressed.

At this time, the insulating layer 51 on the stepped region SRg is preferably divided into a size capable of sufficiently suppressing the compressive stress and is block-nized. Therefore, a plurality of the slits SSs may be formed as needed.

The formation locations, number, interval, or the like of the slits SSs can be determined based on, for example, stress simulation. As an example of such stress simulation, the compressive stress of the insulating layer 51 on the stepped region SRg can be sufficiently suppressed by setting the interval between the plurality of slit SSs to, for example, 140 μm or less.

As illustrated in FIGS. 7Ba and 7Bb, the gap between the insulating layers OL of the stacked bodies LMag and LMbg is filled with a conductive material such as tungsten, molybdenum and the like. As a result, the stacked bodies LMa and LMb having the word lines WL stacked between the individual insulating layers OL are formed.

Incidentally, before filling the gap between the insulating layers OL with the conductive material, a metal element-containing block layer such as an Al₂O₃ layer and a barrier metal layer such as a TiN layer may be formed on upper and lower surfaces of the insulating layer OL in the order of proximity to the insulating layer OL. At this time, the metal element-containing block layer and the barrier metal layer are also formed at end portions of the insulating layer OL facing the slits ST. In addition, the metal element-containing block layer and the barrier metal layer may also be formed on end surfaces of the insulating layers 51 facing the slits ST, SSs, and SPs, respectively. Between these metal element-containing block layer and barrier metal layer, the barrier metal layer is removed from the inside of each of the slits ST, SSs, and SPs at the time of forming the word line WL. The metal element-containing block layer may remain in the slits ST, SSs, and SPs even after the subsequent processing.

The processing illustrated in FIGS. 7Aa to 7Bb is sometimes referred to as a replacement process of the word line WL or the like.

After the formation of the word line WL, the insulating layer 53 (see FIG. 1D) and the like are collectively formed on a side wall of each of the slits ST, SSs, and SPs, and the inside of the insulating layer 53 is filled collectively with, for example, the filling layer 21 (see FIG. 1D), such as the tungsten layer, and the like As a result, the contact LI and the split bands BSs and BPs are formed in the slits ST, SSs and SPs, respectively.

Here, the filling layer 21 such as the tungsten layer has tensile stress. Therefore, since the split bands BSs and BPs having the filling layer 21 and the like are formed, the peripheral configurations thereof are pulled toward the split bands BSs and BPs. Accordingly, for example, the compressive stress from the insulating layer 51 above and outside the stepped region SR is further mitigated.

In addition, tensile stress is generated by the word line WL, which is the tungsten layer or the like, in the inward direction of the stacked bodies LMa and LMb after the replacement process. The split bands BSs and BPs generate stress that pulls the stacked bodies LMa and LMb to the outer side against the tensile stress caused by the word line WL.

As a result, for example, the columnar body HR formed in the stepped region SR is suppressed from being inclined toward the inner side of the stacked bodies LMa and LMb by the compressive stress from the insulating layer 51 and the tensile stress caused by the word line WL.

Thereafter, the contact CC (see FIG. 1B), which penetrates the insulating layer 51 above the stepped region SR and the insulating layer OL on the terrace surface in each step of the stepped region SR and reaches the word line WL on the lower layer, is formed. At this time, since the inclination of the columnar body HR is suppressed by the stress mitigation of the split bands BSs and BPs, the contact between the columnar body HR and the contact CC is suppressed.

In addition, the insulating member SHE, which splits the conductive layer above the word line WL on the uppermost layer, is formed on the stacked bodies LMa and LMb in the memory region MR. In addition, an upper layer wiring connected to the contacts CC and LI, the channel layer CN of the pillar PL, and the like is formed.

As described above, the semiconductor storage device 10 of the first embodiment is manufactured.

The three-dimensional nonvolatile memory is formed, for example, by arranging the memory cells three-dimensionally in the stacked body in which the plurality of conductive layers is stacked with the insulating layers interposed therebetween. On the other hand, the thick insulating layer is arranged outside the stacked body, and a constituent material is significantly different from that of the stacked body having the stacked structure.

Therefore, compressive stress is sometimes generated from the thick insulating layer toward the inner side of the stacked body. During the replacement, the stacked body has the fragile configuration with multiple gaps, and thus, there is a case where the compressive stress from the insulating layer causes the flexure in the stacked structure of the stacked body or the inclination of the columnar body in the stepped region toward the memory region.

Therefore, it is conceivable to mitigate such compressive stress by forming a groove, which divides the stacked body and the insulating layer outside the stacked body, outside the stacked body. In addition, for example, it is conceivable to arrange the plurality of columnar bodies supporting the stacked body at a high density in the stepped region where no memory cell is arranged.

However, the above-described effect of the groove is limited to a predetermined range, and there is a case where an external force acting on the stepped region is not sufficiently suppressed, for example, when viewed locally. In addition, when entirely viewing the stacked body, there is a case where tensile stress to pull the stacked body toward the groove is generated due to the formation of the above-described groove. In addition, the area of the stepped region is limited, and the number of columnar bodies that can be arranged is also limited.

According to the semiconductor storage device 10 of the first embodiment, the split band BSs, which extends in the Y direction intersecting the ascending/descending direction of the stepped region SR and in the stacking direction of the stacked bodies LMa and LMb and splits the insulating layer 51 on the stepped region SR, is provided. As a result, when the sacrificial layer NL is removed in the replacement process, the compressive stress from the insulating layer 51 on the stepped region SRg to the stepped region SRg is suppressed.

Accordingly, it is possible to prevent the vertically adjacent insulating layers OL in the stepped region SRg from flexing to come into contact with each other, and prevent the word line WL from being cut off to be open at such a portion. In addition, the strength desired for the insulating layer OL is lowered, and the insulating layer OL can be thinner, so that the volume of the semiconductor storage device 10 can be reduced.

In addition, the inclination of the columnar body HR of the stepped region SRg toward the inner side of the stacked bodies LMag and LMbg is suppressed, and it is possible to prevent the contact CC and the columnar body HR from coming into contact with each other, for example, when the contact CC is formed.

According to the semiconductor storage device 10 of the first embodiment, the split band BPs, which extends in the Y direction and the thickness direction of the insulating layer 51 and penetrates the insulating layer 51 outside the stepped region SR, is provided. Since both the split bands BSs and BPs are provided in this manner, it is possible to prevent the stacked bodies LMag and LMbg from being pulled toward the slit SPs when the sacrificial layer NL is removed in the replacement process.

Accordingly, the inclination of the columnar body HR of the stepped region SRg toward the slit SPs is suppressed, and it is possible to prevent the contact CC and the columnar body HR from coming into contact with each other, for example, when the contact CC is formed.

According to the semiconductor storage device 10 of the first embodiment, the split band BSs contains tungsten or the like having tensile stress inside. As a result, it is possible to mitigate the compressive stress from the insulating layer 51 on the stepped region SR to the stepped region SR after the replacement process of the word line WL. In addition, even if the tensile stress caused by the word line WL is generated in the stacked bodies LMa and LMb after the replacement process, this tensile stress can be offset and suppressed.

Accordingly, the columnar body HR of the stepped region SR after the replacement process is suppressed from being inclined to the inner side of the stacked bodies LMa and LMb, and it is possible to prevent the contact CC and the columnar body HR from coming into contact with each other, for example, when the contact CC is formed.

According to the semiconductor storage device 10 of the first embodiment, the plurality of split bands BSs may be arranged in the stepped region SR, and the insulating layer 51 on the stepped region SR may be further divided into a large number of blocks. As a result, when the sacrificial layer NL is removed in the replacement process, the compressive stress from the insulating layer 51 on the stepped region SRg to the stepped region SRg can be further mitigated.

According to the semiconductor storage device 10 of the first embodiment, the width of the split band BPs in the X direction is wider than the width of the split band BSs in the X direction. In addition, an aspect ratio of the split band BSs is higher than an aspect ratio of the split band BPs. As a result, the slit SSs, which is to serve as the split band BSs later, does not reach the terrace surface of the stepped region SR and can be formed collectively with the slit SPs which is to serve as the split band BPs later.

Accordingly, for example, the contact between the split band BSs having the conductive filling layer 21 and the word line WL of the stepped region SR is suppressed. However, the split band BSs is not connected to, for example, an upper layer wiring or the like, and is not electrically connected to the other configurations. Therefore, even if the slit SSs comes into contact with one of the word lines WL on surface layers of the stacked bodies LMa and LMb, it is considered that there is no or limited effect on the semiconductor storage device 10.

Incidentally, for example, one split band BPs is arranged outside the stepped region SR in the above-described first embodiment. However, a plurality of the split bands BPs may be arranged outside the stepped region SR.

In addition, when arranging the split band BSs in the stepped region SR, it is possible to arrange the plurality of split bands BSs in close proximity to each other instead of arranging one split band BSs at each location. It is possible to adjust stress balance such as the compressive stress of the insulating layer 51 and the tensile stress caused by the word line WL and the split band BPs to a desired value by adjusting the number of split bands BSs to be arranged at one location, and to further reduce the effect of stress on the stepped region SR.

In this manner, it is possible to arrange the plurality of split bands BSs on the stepped region SR, including the case where the insulating layer 51 on the stepped region SR is divided into a plurality of blocks. FIGS. 7Ca to 7Db illustrate some examples of the case where the plurality of split bands BSs is arranged.

FIGS. 7Ca and 7Cb are views illustrating examples of a plurality of split bands BSsb of a semiconductor storage device according to a first modification of the first embodiment. As illustrated in FIGS. 7Ca and 7Cb, the plurality of split bands BSsb is arranged above the stepped region SR to be spaced at a predetermined distance, thereby dividing the insulating layer 51 on the stepped region SR into a plurality of blocks having a predetermined size. As a result, the compressive stress from the insulating layer 51 on the stepped region SR to the stepped region SR is suppressed.

Incidentally, when there is a possibility that lower surfaces of some of the split bands BSsb may come into contact with the stacked body LMb or the like constituting the stepped region SR by arranging the plurality of split bands BSsb to be spaced on the stepped region SR, the split bands BSsb may be filled with an insulating layer such as a SiO₂ layer.

FIGS. 7Da and 7Db are views illustrating examples of a plurality of split bands BSss of a semiconductor storage device according to a second modification of the first embodiment. As illustrated in FIGS. 7Da and 7Db, the plurality of split bands BSss is arranged in close proximity at predetermined positions above the stepped region SR. As a result, it is easier to adjust the stress balance acting between the respective configurations around the split bands BSss.

Further, the slit ST is filled with the tungsten layer or the like in the above-described first embodiment. However, instead of or in addition to the tungsten layer, the slit ST may be filled with a conductive layer such as a polysilicon layer.

In addition, the slit ST is filled with the conductive layer so as to function as, for example, the source line contact in the above-described first embodiment. However, the slit ST may be used exclusively for the replacement process of the word line WL, and then, may be filled with an insulating layer such as a SiO₂ layer so as not to contribute to the function of the semiconductor storage device 1.

In the above case, the slits SSs and SPs may also be filled with a conductive layer or an insulating layer similarly to the slit ST. Even in this case, an effect of suppressing the stress by the slits SSs and SPs can be obtained at least when the sacrificial layer NL is removed by the replacement process.

Incidentally, when the split bands BSs and BPs are filled with, for example, an insulating layer similarly to the slit ST, the presence of the split bands BSs and BPs in the semiconductor storage device 10 can be determined, for example, depending on whether or not a metal element-containing block layer such as an Al₂O₃ layer interposed between each of the split bands BSs and BPs and the insulating layer 51 is detected.

### Second Embodiment

Hereinafter, a second embodiment will be described in detail with reference to the drawings. In the second embodiment, a manufacturing procedure of the semiconductor storage device is different from that of the first embodiment described above.

(Configuration Example of Semiconductor Storage Device)

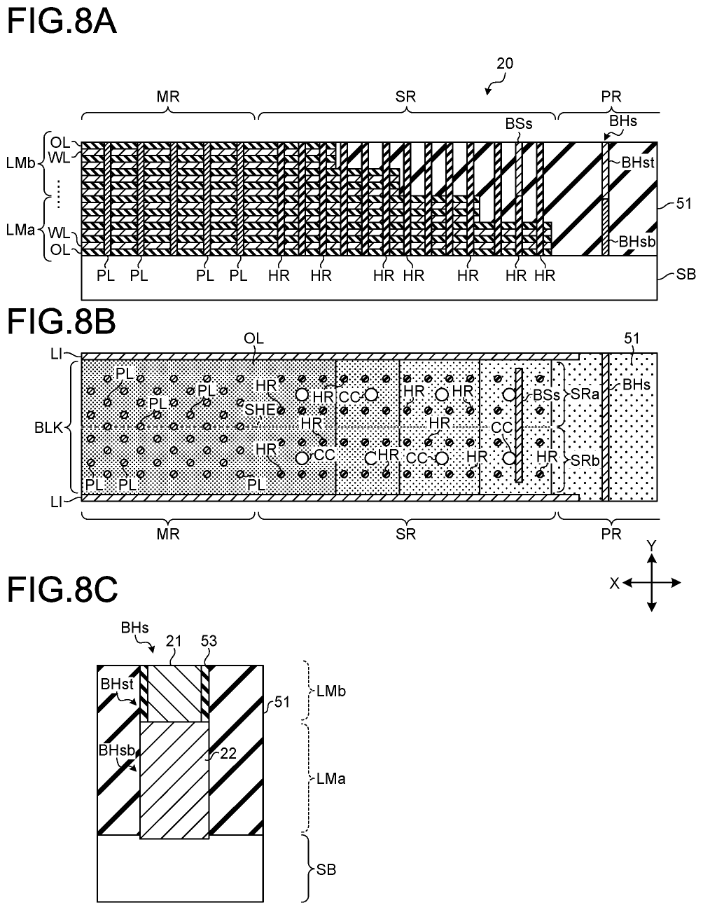

FIGS. 8A to 8C are schematic views illustrating configuration examples of a semiconductor storage device 20 according to the second embodiment. FIG. 8A is a cross-sectional view of the semiconductor storage device 20 taken along the X direction, FIG. 8B is a plan view of the semiconductor storage device 20, and FIG. 8C is an enlarged cross-sectional view of a split band BHs of the semiconductor storage device 20 taken along the X direction. However, an upper layer wiring or the like of the pillar PL and the contacts CC and LI is omitted in FIGS. 8A to 8C.

As illustrated in FIGS. 8A to 8C, the semiconductor storage device 20 of the second embodiment includes the split band BHs, which has a configuration different from that of the above-described split band BPs of the first embodiment, outside the stepped region SR. Hereinafter, configurations different from those of the above-described first embodiment of the semiconductor storage device 20 will be described in detail.

The split band BHs as a second structure is arranged outside the stepped region SR near a terminal end portion of the contact LI in the X direction. The split band BHs extends in the Y direction, and penetrates the insulating layer 51 to reach the substrate SB. The width of the split band BHs in the X direction is approximately equal to, for example, the width of the split band BSs in the X direction. Alternatively, the width of the split band BHs in the X direction is wider than, for example, the width of the split band BSs in the X direction regardless of the examples of FIGS. 8A and 8B.

The split band BHs includes an upper split band BHst and a lower split band BHsb below the upper split band BHst. The upper split band BHst extends from an upper surface of the insulating layer 51 to the lower side of the insulating layer 51 and is connected to the lower split band BHsb, for example. The lower split band BHsb extends in the lower side of the insulating layer 51 from a height position of a connecting part with the upper split band BHst and reaches the substrate SB. The connecting part between the upper split band BHst and the lower split band BHsb is arranged near a height position of an upper surface of the stacked body LMa which is in contact with a bottom surface of the stacked body LMb, for example.

However, a lower end of the upper split band BHst and an upper end of the lower split band BHsb are not necessarily connected as long as both the ends are sufficiently close to each other. States where the upper split band BHst and the lower split band BHsb are not connected may include a case where a gap is generated between the lower end of the upper split band BHst and the upper end of the lower split band BHsb in the thickness direction of the insulating layer 51, for example, since the lower end of the upper split band BHst is located to be shallower than the height position of the upper surface of the stacked body LMa. Alternatively, there may be a case where a gap is generated between the lower end of the upper split band BHst and the upper end of the lower split band BHsb in the X direction since an X-direction position of the upper split band BHst deviates from an X-direction position of the lower split band BHsb.

Even in these cases, a function of the split band BHs for mitigating stress of the insulating layer 51 can be obtained as will be described later if the gap between the lower end of the upper split band BHst and the upper end of the lower split band BHsb is sufficiently small and the upper split band BHst and the lower split band BHsb are in a state of substantially penetrating the insulating layer 51.

The upper split band BHst has an internal configuration similar to, for example, the split band BSs. That is, the upper split band BHst has the insulating layer 53, such as a SiO₂ layer, covering a side wall of the upper split band BHst. The filling layer 21 filled with, for example, tungsten or the like as a first material having tensile stress is arranged inside the insulating layer 53.

In this manner, the insulating layer 53 in the upper split band BHst is made of the same material as the insulating layer 53 covering the side wall of the split band BSs, for example. The filling layer 21 in the upper split band BHst is made of the same material as the filling layer 21 arranged in the split band BSs, for example.

Incidentally, a metal element-containing block layer such as an Al₂O₃ layer (not illustrated) may be interposed between an end surface of the insulating layer 51 facing the upper split band BHst and the insulating layer 53 of the upper split band BHst similar to the case of the split band BSs.

Inside the lower split band BHsb, a filling layer 22 filled with, for example, amorphous silicon or the like as a second material having tensile stress is arranged. The tensile stress of the filling layer 22 is larger than, for example, the tensile stress of the filling layer 21 described above. The filling layer 22 in the lower split band BHsb is made of, for example, the same material as a sacrificial layer filling the inside of the hole HLa which will be described later.

(Method for Manufacturing Semiconductor Storage Device)

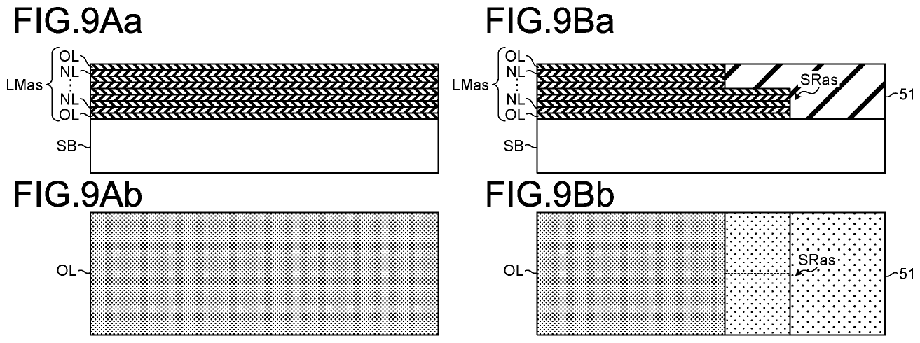

Next, an example of a method for manufacturing the semiconductor storage device 20 of the second embodiment will be described with reference to FIGS. 9Aa to 15Ab.

FIGS. 9Aa to l5Ab are views illustrating examples of a procedure of the method for manufacturing the semiconductor storage device 20 according to the second embodiment. In the same drawing numbers A and B of FIGS. 9Aa to 15Ab, a and b indicated by lowercase letters represent a cross section and a plane, respectively, during the same processing process. The lowercase letter a in FIGS. 9Aa to l5Ab corresponds to the cross section of FIG. 8A, and the lowercase letter b corresponds to the plane of FIG. 8B.

The processing illustrated in FIGS. 9Aa to 9Bb is similar to the processing illustrated in FIGS. 2Aa to 2Bb of the first embodiment described above. That is, the stacked body LMas is formed on the substrate SB as illustrated in FIGS. 9Aa and 9Ab, and the stepped region SRas is formed in the stacked body LMas and covered with the insulating layer 51 as illustrated in FIGS. 9Bb and 9Bb.

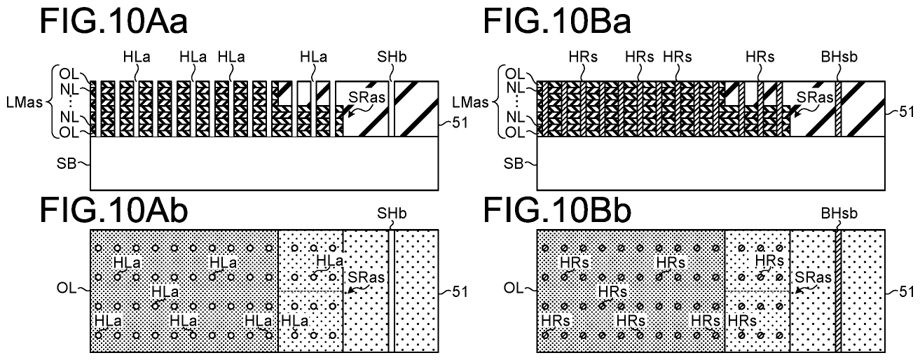

As illustrated in FIGS. 10Aa and 10Ab, a plurality of holes HLa is formed near an end portion of the stacked body LMas including the stepped region SRas. In addition, in parallel with the above process, a slit SHb is formed outside the stepped region SRas of the stacked body LMas. The slit SHb is a portion that is to serve as the lower split band BHsb of the split band BHs later, extends in the Y direction, and penetrates the insulating layer 51 to reach the substrate SB.

Incidentally, at the time of forming the slit SHb, it is desirable to adjust the width of the slit SHb in the X direction or the like to cause aspect ratios to match with each other such that the slit SHb and the hole HLa have substantially the same etching rate and both the slit SHb and hole HLa reach the substrate SB substantially at the same time.

As illustrated in FIGS. 10Ba and 10Bb, the individual holes HLa are filled with sacrificial layers such as amorphous silicon layers to form the columnar bodies HRs. At this time, the slit SHb is also filled with an amorphous silicon layer or the like so that the lower split band BHsb having the filling layer 22 (see FIG. 8C) inside is formed.

Here, the amorphous silicon layer or the like has larger tensile stress than, for example, the tungsten layer. Therefore, at this point, the stacked body LMas is pulled outward by the filling layer 22 of the lower split band BHsb, and an effect of mitigating the compressive stress from the insulating layer 51 outside the stepped region SRas to the stacked body LMa begins to act.

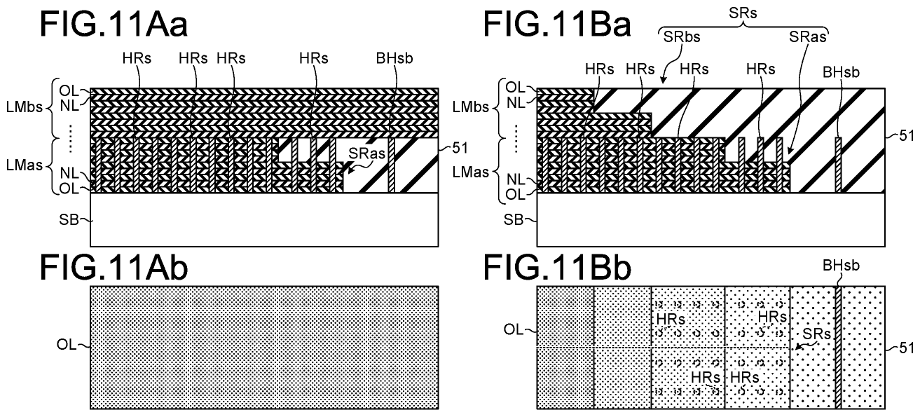

As illustrated in FIGS. 11Aa and 11Ab, the stacked body LMbs is formed on the upper surfaces of the stacked body LMas and the insulating layer 51.

As illustrated in FIGS. 11Ba and 11Bb, the stepped region SRbs is formed in the stacked body LMbs, and the stepped region SRs including the stepped regions SRas and SRbs is formed.

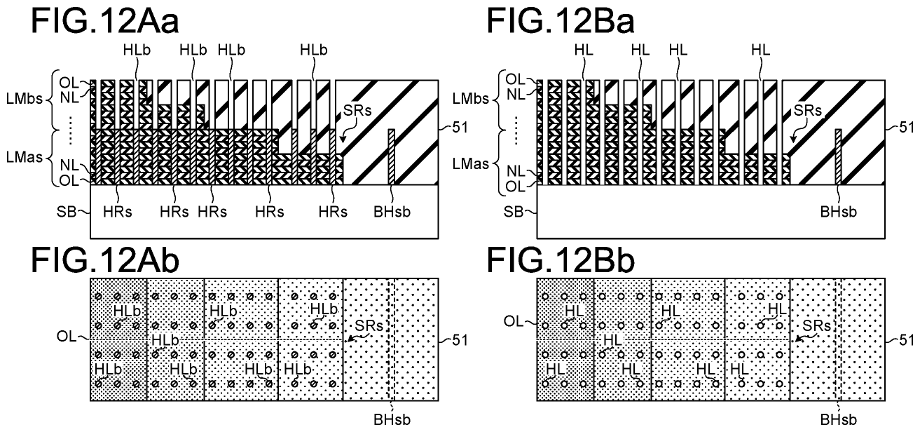

As illustrated in FIGS. 12Aa and 12Ab, a plurality of holes HLb, which reaches a height position of the upper surface of the stacked body LMas in contact with a bottom surface of the stacked body LMbs from the upper surface of the stacked body LMbs in the unprocessed part or the upper surface of the insulating layer 51, is formed above the individual columnar bodies HRs. As a result, the individual holes HLb and the columnar bodies HRs are connected.

As illustrated in FIGS. 12Ba and 12Bb, the sacrificial layers filling the columnar bodies HRs are removed through the holes HLb to form the plurality of holes HL that reach the substrate SB from the height position of the upper surface of the stacked body LMbs in an unprocessed part.

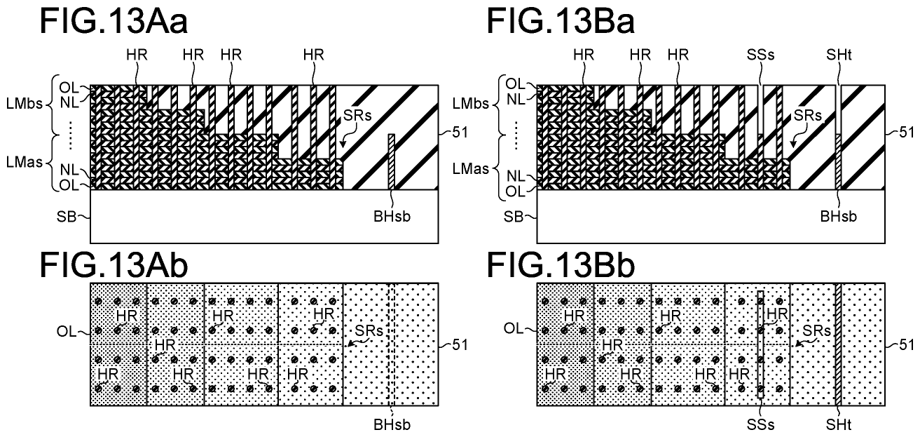

As illustrated in FIGS. 13Aa and 13Ab, the individual holes HL are filled with insulating layers to form the plurality of columnar bodies HR.

Incidentally, the plurality of pillars PL is also formed in the memory region MR through the above processing in the semiconductor storage device 20 of the second embodiment, which is similar to the case of the first embodiment described above.

As illustrated in FIGS. 13Ba and 13Bb, slits SSs and SHt are formed, for example, collectively. At least one or a plurality of slits SSs may be formed in the stepped region SRs. The slit SHt is a portion which is to serve as the upper split band BHst later, and extends in the Y direction.

It is preferable that the slits SSs and SHt have aspect ratios, which match with each other, by adjusting the width and the like in the X direction such that etching depths in the insulating layer 51 are set to desired depths, respectively. At this time, the aspect ratio of the slit SSs may be equal to or higher than the aspect ratio of the slit SHt.

As a result, an etching process of the slit SSs can be completed without reaching a terrace surface of a predetermined step of the stepped region SRs, and further, an etching process of the slit SHt can be completed in the state of being connected to the lower split band BHsb more reliably.

However, there may be a case where the slit SHt is not connected to the lower split band BHsb since the slit SHt is processed to be shallower than the desired etching depth. Alternatively, there may be a case where the slit SHt is not connected to the lower split band BHsb since the slit SHt is formed so as to have an X-direction position deviating from an X-direction position of the lower split band BHsb. Even in these cases, the expansion of the insulating layer 51 in the X direction can be interrupted by the split band BHs to be formed later to such an extent that stress mitigation of the insulating layer 51 is possible if a distance between a lower end portion of the slit SHt and an upper end of the lower split band BHsb is sufficiently close.

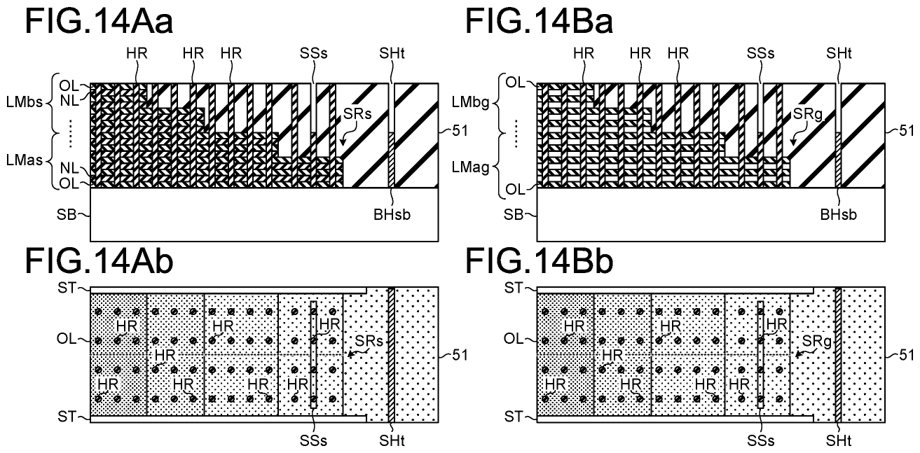

As illustrated in FIGS. 14Aa and 14Ab, the slit ST, which extends in the X direction and penetrates the stacked bodies LMas and LMbs to reach the substrate SB, is formed. At this time, an aspect ratio may be adjusted based on the width of the slit ST in the Y direction or the like such that a desired etching rate can be obtained. For example, the aspect ratio of the slit ST is equal to or lower than the aspect ratios of the slits SSs and SHt, and is preferably lower than the aspect ratios of the slits SSs and SHt.

As illustrated in FIGS. 14Ba and 14Bb, the sacrificial layer NL of the stacked bodies LMas and LMbs is removed through the slit ST to form the stacked bodies LMag and LMbg having a gap between the insulating layers OL. At this time, since the slits SSs and SHt that divide the insulating layer 51 are formed, the compressive stress from the insulating layer 51 to the stacked bodies LMag and LMbg and the stepped region SRg is mitigated.

In addition, amorphous silicon or the like with which the lower split band BHsb is filled is a material having larger tensile stress than, for example, tungsten or the like. Therefore, the compressive stress of the insulating layer 51 is further mitigated by the lower split band BHsb.

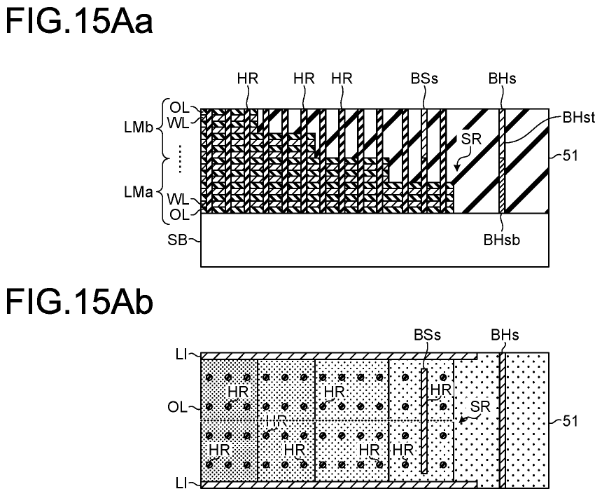

As illustrated in FIGS. 15Aa and 15Ab, the gap between the insulating layers OL of the stacked bodies LMag and LMbg is filled with a conductive material through the slit ST to form the word line WL. For example, tensile stress is generated in the stacked bodies LMa and LMb due to the word line WL. However, the larger tensile stress acts toward the outer side of the stacked bodies LMa and LMb due to the lower split band BHsb filled with amorphous silicon or the like, and thus, the tensile stress caused by the word line WL is suppressed.

Incidentally, before forming the word line WL, a metal element-containing block layer such as an Al₂O₃ layer and a barrier metal layer such as a TiN layer may be formed on upper and lower surfaces and an end portion close to the slit ST of the insulating layer OL in the order of proximity to the insulating layer OL. These metal element-containing block layer and barrier metal layer may be formed on end surfaces of the insulating layer 51 facing the slits ST, SSs, and SHt. Between the metal element-containing block layer and barrier metal layer, the barrier metal layer is removed from the inside of each of the slits ST, SSs, and SHt at the time of forming the word line WL.

After the formation of the word line WL, the insulating layer 53 and the like are collectively formed on a side wall of each of the slits ST, SSs, and SHt, and the inside of the insulating layer 53 is filled collectively with, for example, the filling layer 21, such as the tungsten layer, and the like. As a result, the contact LI, the split band BSs, and the upper split band BHst are formed in the slits ST, SSs, and SHt, respectively. In addition, the split band BHs including the upper split band BHst and the lower split band BHsb is formed.

Thereafter, the contact CC, which penetrates the insulating layer 51 above the stepped region SR and the insulating layer OL on the terrace surface in each step of the stepped region SR and reaches the word line WL on the lower layer, is formed. At this time, the compressive stress from the insulating layer 51 and the tensile stress caused by the word line WL are suppressed by the split bands BSs and BHs, and thus, the inclination of the columnar body HR is suppressed, and the contact between the columnar body HR and the contact CC is suppressed.

In addition, the insulating member SHE, which splits the conductive layer above the word line WL on the uppermost layer, is formed in the memory region MR of the stacked bodies LMa and LMb. In addition, an upper layer wiring connected to the contacts CC and LI, the channel layer CN of the pillar PL, and the like is formed.

As described above, the semiconductor storage device 20 of the second embodiment is manufactured.

According to the semiconductor storage device 20 of the second embodiment, the split band BSs that splits the insulating layer 51 on the stepped region SR and the split band BHs that penetrates the insulating layer 51 outside the stepped region SR are provided. As a result, the effect similar to that of the semiconductor storage device 10 of the first embodiment described above is obtained.

According to the semiconductor storage device 20 of the second embodiment, the upper split band BHst of the split band BHs contains tungsten or the like, and the lower split band BHsb of the split band BHs contains amorphous silicon having tensile stress and the like. As a result, when the sacrificial layer NL is removed in a replacement process, the compressive stress from the insulating layer 51 outside the stacked bodies LMag and LMbg to the stacked bodies LMag and LMbg can be mitigated.

According to the semiconductor storage device 20 of the second embodiment, the aspect ratio of the split band BSs is equal to or higher than the aspect ratio of the upper split band BHst. As a result, the slit SSs, which is to serve as the split band BSs later, does not reach the terrace surface of the stepped region SR and can be formed collectively with the slit SHt which is to serve as upper split band BHst later. Accordingly, for example, the contact between the split band BSs having the conductive filling layer 21 and the word line WL of the stepped region SR is suppressed.

Incidentally, for example, a plurality of the split bands BHs may be arranged outside the stepped region SR in the second embodiment as well. In addition, a plurality of the split bands BSs may be arranged close to each other at the time of arranging the split band BSs in the stepped region SR.

In addition, the slit ST may be filled with a conductive material such as polysilicon as the first material, instead of or in addition to tungsten as the first material, in the second embodiment as well. In addition, the slit ST may be filled with an insulating material such as SiO₂ as the first material, instead of the conductive material.

Along with the above configuration, the slits SSs and SHt may also be filled with the conductive material or insulating material similar to the slit ST. In this case, the split band BHs outside the stepped region SR includes, for example, the upper split band BHst filled with the conductive material such as the polysilicon layer as the first material, and the lower split band BHsb filled with the amorphous silicon or the like as the second material. Alternatively, the split band BHs includes, for example, the upper split band BHst filled with the insulating material such as SiO₂ as the first material, and the lower split band BHsb filled with the amorphous silicon or the like as the second material.

As described above, the upper split band BHst does not necessarily have a material having tensile stress. Even in this case, an effect of suppressing the stress by the slits SSs and SHt can be obtained at least when the sacrificial layer NL is removed by the replacement process. In addition, the effect of suppressing the stress by the lower split band BHsb can be obtained.

Incidentally, when the split band BSs and the upper split band BHst are filled with, for example, an insulating layer similarly to the slit ST, the presence of the split band BSs and the upper split band BHst in the semiconductor storage device 20 can be determined, for example, depending on whether or not a metal element-containing block layer such as an Al₂O₃ layer interposed between each of the split band BSs and the upper split band BHst and the insulating layer 51 is detected.

### Third Embodiment

Hereinafter, a third embodiment will be described in detail with reference to the drawings. In the third embodiment, a configuration of a split band provided in the semiconductor storage device is different from those of the above-described first and second embodiments.

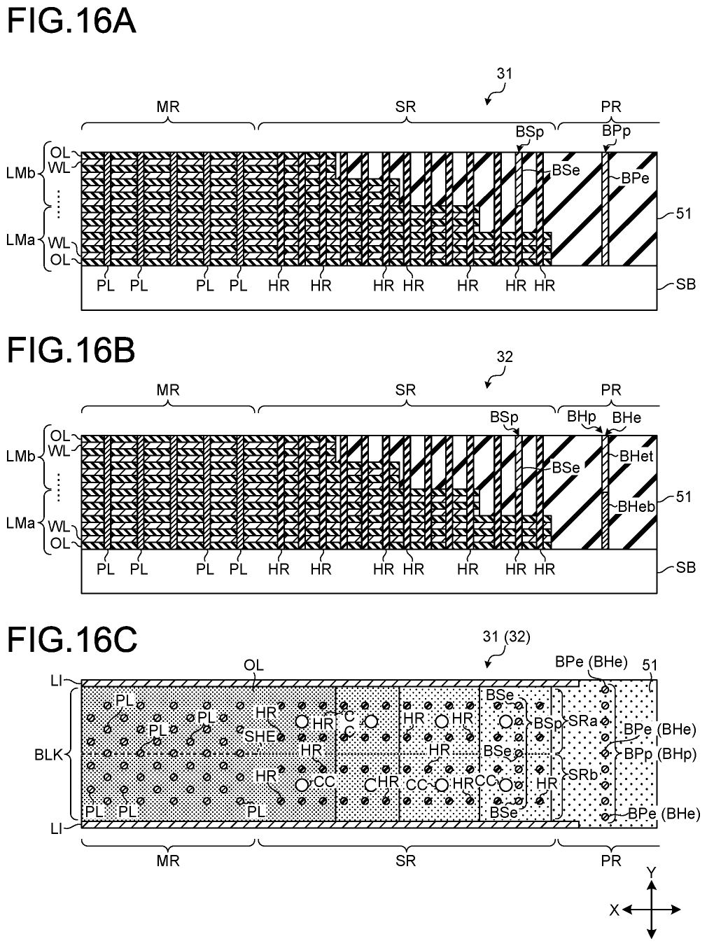

FIGS. 16A to 16C are schematic views illustrating configuration examples of semiconductor storage devices 31 and 32 according to the third embodiment. FIG. 16A is a cross-sectional view of the semiconductor storage device 31 taken along the X direction, FIG. 16B is a cross-sectional view of the semiconductor storage device 32 taken along the X direction, and FIG. 16C is a plan view of the semiconductor storage device 31 or 32. However, an upper layer wiring or the like of the pillar PL and the contacts CC and LI is omitted in FIGS. 16A to 16C.

As illustrated in FIGS. 16A and 16C, the semiconductor storage device 31 of the third embodiment includes split bands BSp and BPp having configurations different from those of the split bands BSs and BPs of the first embodiment described above. Hereinafter, configurations different from those of the above-described first embodiment of the semiconductor storage device 31 will be described in detail.

The split band BSp as a first structure is located above the stepped region SR sandwiched between the two contacts LI. The split band BSp is arrayed in the Y direction and includes a plurality of columnar portions BSe extending to the middle of the insulating layer 51 on the stepped region SR. In the split band BSp, these individual columnar portions BSe interrupt the spread of the insulating layer 51 on the stepped region SR in the X direction. However, each of the columnar portions BSe does not completely penetrate the insulating layer 51, and a bottom surface of each of the columnar portions BSe is not in contact with the stacked bodies LMa and LMb in the stepped region SR. That is, lower ends of the individual columnar portions BSe are located above upper surfaces of the stacked bodies LMa and LMb in the stepped region SR.

At least one split band BSp can be arranged in the stepped region SR. A plurality of the split bands BSp may be arranged in the stepped region SR. In such a case, the plurality of split bands BSp may be arranged at substantially equal intervals, for example. The interval between the plurality of split bands BSp can be set to, for example, 140 μm or less.

Each of the columnar portions BSe of the split band BSp has, for example, the internal configuration similar to the split band BSs of the first embodiment described above. That is, the columnar portion BSe has an insulating layer such as a SiO₂ layer covering a side wall of the columnar portion BSe, which is similar to the insulating layer 53 described above. A filling layer filled with a material having tensile stress, such as tungsten, is arranged inside the insulating layer, which is similar to the filling layer 21 described above.

Incidentally, a metal element-containing block layer, such as an Al₂O₃ layer, may be interposed between an end surface of the insulating layer 51 facing the columnar portion BSe and the insulating layer of the columnar portion BSe similar to the case of the split band BSs of the first embodiment described above.

In addition, a pitch in the array of the plurality of columnar portions BSe, that is, the pitch in the Y direction is smaller than, for example, a pitch of the columnar bodies HR in the Y direction. It is possible to adjust stress balance such as the compressive stress of the insulating layer 51 and tensile stress caused by the word line WL and the split band BPp to a desired value by adjusting the pitch of the columnar portion BSe, and to reduce the effect of stress on the stepped region SR.

Since the pitch of the columnar portion BSe is different from the pitch of the columnar body HR, for example, in this manner, the columnar body HR is not necessarily arranged below the columnar portion BSe. When an arrangement location of the columnar portion BSe coincides with an arrangement location of the columnar body HR, an upper portion of the columnar body HR disappears due to the columnar portion BSe.

The split band BPp as the second structure is arranged outside the stepped region SR near a terminal end portion of the contact LI in the X direction. The split band BPp is arrayed in the Y direction and includes a plurality of columnar portions BPe that penetrate the insulating layer 51 to reach the substrate SB. In the split band BPp, these individual columnar portions BPe interrupt the spread of the insulating layer 51 outside the stepped region SR in the X direction.

Each of the columnar portions BPe of the split band BPp has, for example, the internal configuration similar to the split band BPs of the first embodiment described above. That is, the columnar portion BPe has an insulating layer such as a SiO₂ layer covering a side wall of the columnar portion BPe, which is similar to the insulating layer 53 described above. A filling layer filled with a material having tensile stress, such as tungsten, is arranged inside the insulating layer, which is similar to the filling layer 21 described above.

Incidentally, a metal element-containing block layer, such as an Al₂O₃ layer, may be interposed between an end surface of the insulating layer 51 facing the columnar portion BPe and the insulating layer of the columnar portion BPe similar to the case of the split band BPs of the first embodiment described above.

In addition, a pitch in the array of the plurality of columnar portions BPe, that is, the pitch in the Y direction, is preferably smaller than the pitch of the columnar body HR in the Y direction, for example, and may be substantially equal to, for example, the pitch of the columnar portion BSe described above. It is possible to adjust stress balance such as the compressive stress of the insulating layer 51 and the tensile stress caused by the word line WL to a desired value by adjusting the pitch of the columnar portion BPe, and to reduce the effect of stress on the stepped region SR.

In addition, a diameter of each of the columnar portions BPe is larger than a diameter of the columnar portion BSe of the split band BSp, for example. In this case, the width of each of the columnar portions BPe in the X direction may be wider than, for example, the width of the columnar portion BSe of the split band BSp in the X direction although simplified in FIGS. 16A and 16C. As a result, an aspect ratio of a hole, which is to serve as the columnar portion BPe later, is lower than an aspect ratio of a hole which is to serve as the columnar portion BSe later, and it is possible to form, for example, collectively the columnar portions BPe and BSe having different depths of reaching points.

Incidentally, shapes of cross sections in the horizontal direction of these columnar portions BSe and BPe can be arbitrarily selected, such as a substantially perfect circle, an ellipse, and an oval type. The columnar portions BSe and BPe may have different cross-sectional shapes.

As illustrated in FIGS. 16B and 16C, the semiconductor storage device 32 of the third embodiment includes split bands BSp and BHp having configurations different from those of the split bands BSs and BHs of the second embodiment described above. Between these split bands BSp and BHp, the split band BSp has the configuration similar to the split band BSp of the semiconductor storage device 31 of the third embodiment described above.

Hereinafter, the configuration of the split band BHp different from that of the second embodiment of the semiconductor storage device 32 will be described in detail.

The split band BHp as the second structure is arranged outside the stepped region SR near a terminal end portion of the contact LI in the X direction. The split band BHp is arrayed in the Y direction and includes a plurality of columnar portions BHe that penetrate the insulating layer 51 to reach the substrate SB. In the split band BHp, these individual columnar portions BHe interrupt the spread of the insulating layer 51 outside the stepped region SR in the X direction.

Each of the columnar portions BHe includes an upper columnar portion BHet and a lower columnar portion BHeb below the upper columnar portion BHet. The upper columnar portion BHet extends from an upper surface of the insulating layer 51 to the lower side of the insulating layer 51, for example, and is connected to the lower columnar portion BHeb. The lower columnar portion BHeb extends in the lower side of the insulating layer 51 from a height position of a connecting part with the upper columnar portion BHet and reaches the substrate SB.

However, a lower end of the upper columnar portion BHet and an upper end of the lower columnar portion BHeb are not necessarily connected as long as both the ends are sufficiently close to each other. States where the upper columnar portion BHet and the lower columnar portion BHeb are not connected may include a case where the lower end of the upper columnar portion BHet is located to be shallower than the upper end of the lower columnar portion BHeb, a case where the upper columnar portion BHet and the lower columnar portion BHeb deviate from each other in the X direction, and a case where the upper columnar portion BHet and the lower columnar portion BHeb deviate from each other in the Y direction so that a gap is generated between the lower end of the upper columnar portion BHet and the upper end of the lower columnar portion BHeb in the Y direction.

Even in these cases, the expansion of the insulating layer 51 in the X direction can be interrupted by the upper columnar portion BHet and the lower columnar portion BHeb to such an extent that stress mitigation of the insulating layer 51 is possible if the gap between the lower end of the upper columnar portion BHet and the upper end of the lower columnar portion BHeb is sufficiently small and the upper columnar portion BHet and the lower columnar portion BHeb are in a state of substantially penetrating the insulating layer 51.

Incidentally, the array of the upper columnar portions BHet in which the plurality of upper columnar portions BHet is assembled can also be referred to as an upper split band of the third embodiment, and the array of the lower columnar portions BHeb in which the plurality of lower columnar portions BHeb is assembled can also be referred to as a lower split band of the third embodiment.

Each of the upper columnar portions BHet of the split band BHp has, for example, the internal configuration similar to the upper split band BHst of the second embodiment described above. That is, the upper columnar portion BHet has an insulating layer such as a SiO₂ layer covering a side wall of the upper columnar portion BHet, which is similar to the insulating layer 53 described above. A filling layer filled with tungsten or the like as a first material having tensile stress is arranged inside the insulating layer, which is similar to the above-described filling layer 21.

Incidentally, a metal element-containing block layer, such as an Al₂O₃ layer, may be interposed between an end surface of the insulating layer 51 facing the upper columnar portion BHet and the insulating layer of the upper columnar portion BHet similar to the case of the upper split band BHst of the second embodiment described above.

Each of the lower columnar portions BHeb of the split band BHp has, for example, the internal configuration similar to the lower split band BHsb of the second embodiment described above. That is, the lower columnar portion BHeb has a filling layer filled with amorphous silicon or the like as a second material having tensile stress, which is similar to the filling layer 22 described above.

In addition, a pitch in the array of the plurality of columnar portions BHe, that is, the pitch in the Y direction, is preferably smaller than the pitch of the columnar body HR in the Y direction, for example, and may be substantially equal to, for example, the pitch of the columnar portion BSe described above. It is possible to adjust stress balance such as the compressive stress of the insulating layer 51 and the tensile stress caused by the word line WL to a desired value by adjusting the pitch of the columnar portion BHe, and to reduce the effect of stress on the stepped region SR.

In addition, a diameter of each of the columnar portions BHe is substantially equal to a diameter of the columnar portion BSe of the split band BSp, for example. Alternatively, the diameter of each of the columnar portions BHe is larger than the diameter of, for example, the columnar portion BSe regardless of the examples of FIGS. 16B and 16C. In this case, the width of each of the columnar portions BHe in the X direction may be wider than, for example, the width of the columnar portion BSe of the split band BSp in the X direction. As a result, it is possible to cause an aspect ratio of a hole, which is to serve as the upper columnar portion BHet later, and an aspect ratio of a hole, which is to serve as the columnar portion BSe later, to match with each other, and to collectively form these holes at a desired etching rate, for example.

Incidentally, shapes of cross sections of these columnar portions BSe and BHe in the horizontal direction can be arbitrarily selected, such as a substantially perfect circle, an ellipse, and an oval type. The columnar portions BSe and BHe may have different cross-sectional shapes.

The semiconductor storage device 31 of the third embodiment can be manufactured by the procedure similar to the method for manufacturing the semiconductor storage device 10 of the first embodiment described above. The semiconductor storage device 32 of the third embodiment can be manufactured by the procedure similar to the method for manufacturing the semiconductor storage device 20 of the second embodiment described above.

According to the semiconductor storage devices 31 and 32 of the third embodiment, the split band BSp includes the plurality of columnar portions BSe arrayed in the Y direction. In addition, the split band BPp includes the plurality of columnar portions BPe arrayed in the Y direction according to the semiconductor storage device 31 of the third embodiment. In addition, the split band BHp includes the plurality of columnar portions BHe arrayed in the Y direction according to the semiconductor storage device 32 of the third embodiment.

As a result, the effect similar to that of the semiconductor storage devices 10 and 20 of the first and second embodiments described above is obtained.

In addition, various types of stress balances acting on the stacked bodies LMa and LMb and the stepped region SR can be adjusted by adjusting the pitch of each of the columnar portions BSe, BPe, and BHe, and it becomes easier to further reduce the influence of stress on the stacked bodies LMa and LMb and the stepped region SR.

In addition, it becomes easy to cause the aspect ratios of the holes, which are to serve respectively as the columnar portions BSe, BPe, and BHe, to match with each other at the time of forming the respective columnar portions BSe, BPe, and BHe. Accordingly, it becomes easier to collectively form at least some of the columnar portions BSe, BPe, and BHe.

Incidentally, for example, a plurality of the split bands BPp or a plurality of the split bands BHp may be arranged outside the stepped region SR in the third embodiment as well. In addition, a plurality of the split bands BSp may be arranged close to each other at the time of arranging the split bands BSp in the stepped region SR. That is, the plurality of columnar portions BSe may be arranged in close proximity at each location.

In addition, a slit, which is to serve as the contact LI, may be filled with a conductive material such as polysilicon as the first material, instead of or in addition to tungsten as the first material, in the third embodiment as well. In addition, the slit may be filled with an insulating material such as SiO₂ as the first material, instead of the conductive material.

Along with the above configuration, the holes, which are to serve as the columnar portions BSe and BPe and the upper columnar portion BHet later, may also be filled with the conductive material or insulating material similar to the slit. In this case, in the semiconductor storage device 32, the columnar portion BHe outside the stepped region SR includes, for example, the upper columnar portion BHet filled with the conductive material such as polysilicon as the first material, and the lower columnar portion BHeb filled with the amorphous silicon or the like as the second material. Alternatively, the columnar portion BHe includes, for example, the upper columnar portion BHet filled with the insulating material such as SiO₂ as the first material, and the lower columnar portion BHeb filled with the amorphous silicon or the like as the second material.

As described above, the upper columnar portion BHet does not necessarily have a material having tensile stress. Even in this case, an effect of suppressing stress can be obtained due to the array of the plurality of holes which are to serve as the columnar portions BSe, BPe, and BHe, respectively, at least when the sacrificial layer NL is removed in a replacement process. In addition, the effect of suppressing the stress by the lower columnar portion BHeb can be obtained.

Incidentally, when the split bands BSp and BPp and an upper portion of the split band BHp are filled with, for example, an insulating layer similarly to the slit ST, the presence of the split bands BSp and BPp and the upper columnar portion BHet, which is an upper structure of the split band BHp, in the semiconductor storage devices 31 and 32 can be determined, for example, depending on whether or not a metal element-containing block layer such as an Al₂O₃ layer interposed between each of the split bands BSp and BPp and the upper structure of the split band BHp, and the insulating layer 51 is detected.

### Fourth Embodiment

Hereinafter, a fourth embodiment will be described in detail with reference to the drawings. The fourth embodiment is different from the first embodiment in that a pillar, a columnar body, and a split band are formed in parallel.

(Configuration Example of Semiconductor Storage Device)

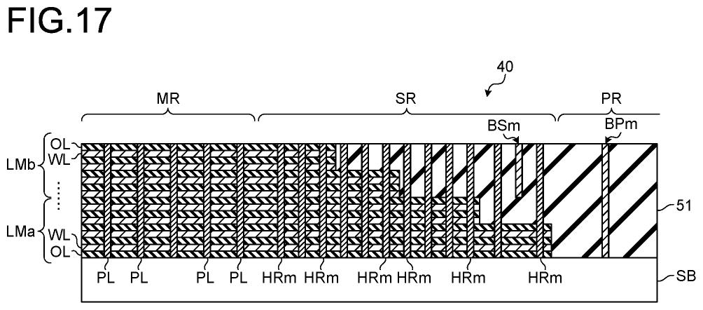

FIG. 17 is a cross-sectional view taken along the X direction illustrating a configuration example of a semiconductor storage device 40 according to the fourth embodiment. However, an upper layer wiring or the like of the pillar PL and the contact CC is omitted in FIG. 17.

As illustrated in FIG. 17, the semiconductor storage device 40 of the fourth embodiment includes columnar bodies HRm having a different configuration from the columnar bodies HR of the first embodiment described above. In addition, the columnar body HRm is not arranged at a position of a split band BSm. Hereinafter, configurations different from those of the above-described first embodiment of the semiconductor storage device 40 will be described in detail.

The plurality of columnar bodies HRm has the configuration similar to the columnar bodies HR of the first embodiment, except that the columnar body HRm has a filler different from that of the columnar body HR of the first embodiment.

Each of the columnar bodies HRm has a size substantially equal to, for example, the pillar PL, and each of the columnar bodies HRm is filled with the material similar to the pillar PL. That is, each of the columnar bodies HRm includes, for example, SiO₂ layer/SiN layer/SiO₂ layer similar to the constituent materials of the memory layer ME, an amorphous silicon layer or a polysilicon layer similar to the constituent material of the channel layer CN, and a SiO₂ layer similar to the constituent material of the core layer CR, in order from the outer peripheral side.

The columnar body HRm is not arranged at the position overlapping the split band BSm as a first structure. Except for this point, the split band BSm has, for example, the configuration similar to the split band BSs of the first embodiment described above.

A split band BPm as a second structure has the configuration similar to the split band BPs of the first embodiment described above, except that the split band BPm is formed by a procedure different from that of the split band BPs of the first embodiment described above.

(Method for Manufacturing Semiconductor Storage Device)

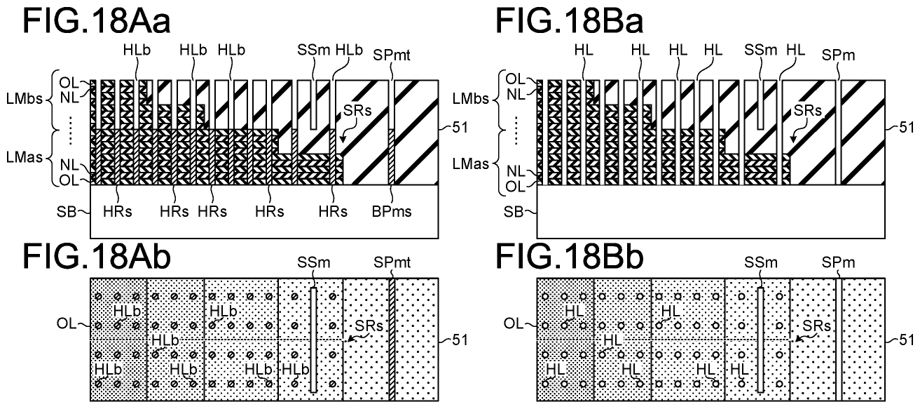

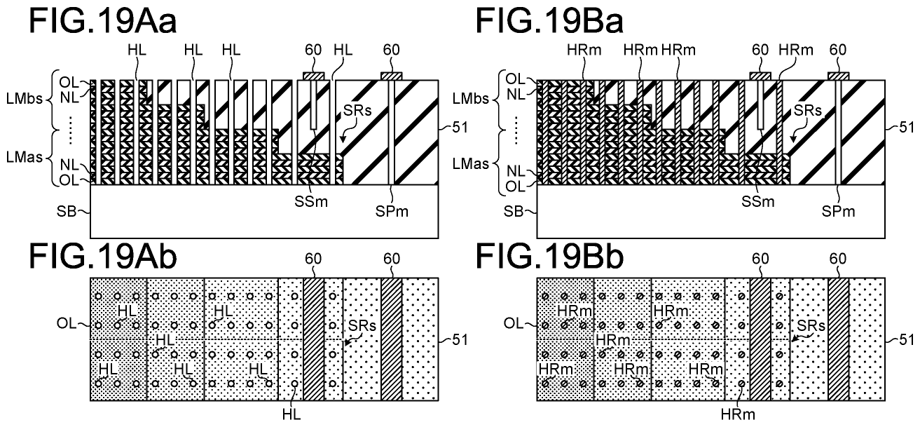

Next, an example of a method for manufacturing the semiconductor storage device 40 of the fourth embodiment will be described by borrowing FIGS. 9Aa to 11Bb of the second embodiment and referring to FIGS. 18Aa to 21Bb.

FIGS. 18Aa to 21Bb are views illustrating examples of a procedure of a method for manufacturing the semiconductor storage device 40 according to the fourth embodiment. In the same drawing numbers A and B of FIGS. 18Aa to 21Bb, a and b indicated by lowercase letters represent a cross section and a plane, respectively, during the same processing process. The lowercase letter a in FIGS. 18Aa to 21Bb corresponds to the cross section of FIG. 17, and the lowercase letter b is the plan view of the semiconductor storage device 40 in the middle of being processed.

The stacked body LMas is formed on the substrate SB as borrowed and illustrated in FIGS. 9Aa and 9Ab, and the stepped region SRas is formed in the stacked body LMas and covered with the insulating layer 51 as illustrated in FIGS. 9Ba and 9Bb.

As illustrated in FIGS. 10Aa and 10Ab, a plurality of holes HLa is formed near an end portion of the stacked body LMas including the stepped region SRas. At this time, the hole HLa is not formed at a position where the split band BSm is to be formed later. In addition, in parallel with the above process, the slit SHb is formed outside the stepped region SRas of the stacked body LMas, and a memory hole (not illustrated) is formed in the memory region MR (not illustrated).

In the fourth embodiment, the slit SHb is a portion that is to serve as a part of the split band BPm later, and extends in the Y direction and penetrates the insulating layer 51 to reach the substrate SB. In addition, it is preferable to cause aspect ratios to consist with each other such that the slit SHb and the hole HLa reach the substrate SB substantially at the same time in the fourth embodiment as well.

As illustrated in FIGS. 10Ba and 10Bb, the individual holes HLa are filled with sacrificial layers such as amorphous silicon layers to form the columnar bodies HRs. At this time, the inside of the slit SHb and the memory hole (not illustrated) are also filled with the amorphous silicon layer or the like.

As described above, an effect of mitigating compressive stress from the insulating layer 51 outside the stepped region SRas to the stacked body LMa is obtained by the slit SHb filled with the sacrificial layer such as the amorphous silicon layer.

As illustrated in FIGS. 11Aa and 11Ab, the stacked body LMbs is formed on the upper surfaces of the stacked body LMas and the insulating layer 51.

As illustrated in FIGS. 11Ba and 11Bb, the stepped region SRbs is formed in the stacked body LMbs, the stepped region SRs including the stepped region SRas and SRbs is formed, and the insulating layer 51 covering the stepped region SRs is formed.

As illustrated in FIGS. 18Aa and 18Ab, a plurality of holes HLb, which reaches a height position of the upper surface of the stacked body LMas in contact with a bottom surface of the stacked body LMbs from the upper surface of the stacked body LMbs in the unprocessed part or the upper surface of the insulating layer 51, is formed above the individual columnar bodies HRs.

In addition, in parallel with the above process, a slit SPmt, which reaches the height position of the upper surface of the stacked body LMas in contact with a bottom surface of the stacked body LMbs from the upper surface of the insulating layer 51, is formed above the split band BPms. The split band BPms is a structure obtained by filling the slit SHb described above with a sacrificial layer such as an amorphous silicon layer.

In addition, in parallel with the formation of the hole HLb, a slit SSm, which extends downward in the insulating layer 51 without reaching a terrace surface of a predetermined step of the stepped region SRs, is formed. The slit SSm is a portion which is to serve as the split band BSm later, and at least one or a plurality of slits SSm is formed in the stepped region SRs.

In addition, in parallel with the formation of the hole HLb, a plurality of memory holes reaching the height position of the upper surface of the stacked body LMas from the upper surface of the stacked body LMbs is formed above the individual memory holes that are formed in the stacked body LMas and are filled with sacrificial layers such as amorphous silicon layers, in the memory region MR (not illustrated).

As illustrated in FIGS. 18Ba and 18Bb, the sacrificial layers filling the columnar bodies HRs are removed through the individual holes HLb to form the plurality of holes HL that reach the substrate SB from the height position of the upper surface of the stacked body LMbs in an unprocessed part.

In addition, in parallel with the above process, the sacrificial layer filling the split band BPms is removed through the slit SPmt to form a slit SPm reaching the substrate SB from the upper surface of the insulating layer 51. As a result, the insulating layer 51 outside the stacked bodies LMas and LMbs is separated from the stacked bodies LMas and LMbs, and the compressive stress from the insulating layer 51 to the stacked bodies LMas and LMbs is mitigated.

In addition, in parallel with the removal of the sacrificial layer of the columnar body HRs, the sacrificial layer in the memory hole formed in the stacked body LMas is removed through the memory hole formed in the stacked body LMbs in the memory region MR (not illustrated). As a result, a memory hole that penetrates the stacked bodies LMas and LMbs and reaches the substrate SB is formed.

As illustrated in FIGS. 19Aa and 19Ab, a mask pattern 60 in which a resist film or the like is patterned so as to cover the slits SSm and SPm is formed on the slits SSm and SPm.

As illustrated in FIGS. 19Ba and 19Bb, in each of the holes HL, for example, SiO₂ layer/SiN layer/SiO₂ layer similar to the constituent materials of the memory layer ME, an amorphous silicon layer or a polysilicon layer similar to the constituent material of the channel layer CN, and a SiO₂ layer similar to the constituent material of the core layer CR are formed in order from the side wall side of the hole HL.

At this time, the amorphous silicon layer or polysilicon layer similar to the constituent material of the channel layer CN may also be formed at a bottom of the hole HL, and further, the SiO₂ layer/SiN layer/SiO₂ layer similar to the constituent materials of the memory layer ME may also be formed at the bottom of the hole HL.

The filling of the hole HL with these materials is performed in parallel with filling of the memory hole with similar materials in the memory region MR (not illustrated). That is, in each memory hole, the memory layer ME including a block insulating layer BK, a charge storage layer CT, and a tunnel insulating layer TN, the channel layer CN, and the core layer CR are formed in order from the side wall side of the memory hole. At this time, the channel layer CN is also formed at a bottom of the memory hole.

As a result, the plurality of columnar bodies HRm is formed in the stepped region SRs. In addition, the plurality of pillars PL (not illustrated) is formed in the memory region MR (not illustrated).

Incidentally, the slits SSm and SPm covered with the mask pattern 60 are not filled with these materials. In addition, the hole HLa is not arranged below the slit SSm, and thus, it is possible to prevent generation of the hole HLa or the hole HL that is not filled with the above materials even if the slit SSm is covered with the mask pattern 60.

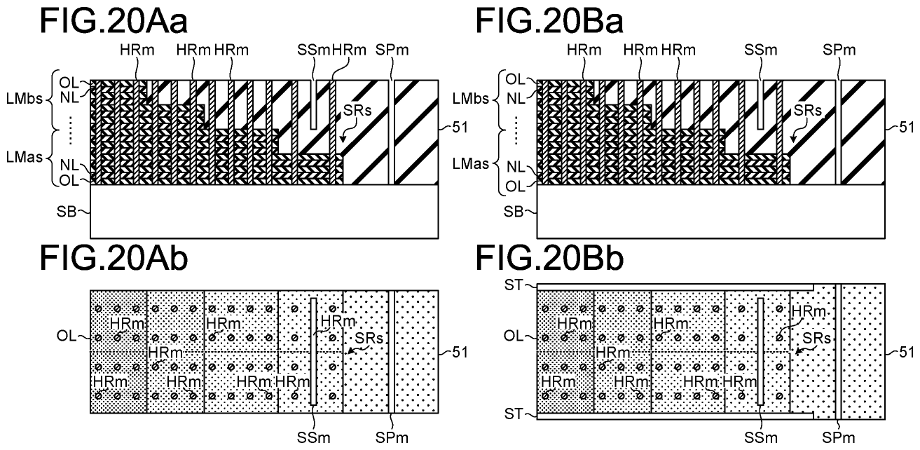

As illustrated in FIGS. 20Aa and 20Ab, the mask pattern 60 on the slits SSm and SPm is removed.

As illustrated in FIGS. 20Ba and 20Bb, the slit ST, which extends in the X direction and penetrates the stacked bodies LMa and LMb to reach the substrate SB, is formed.

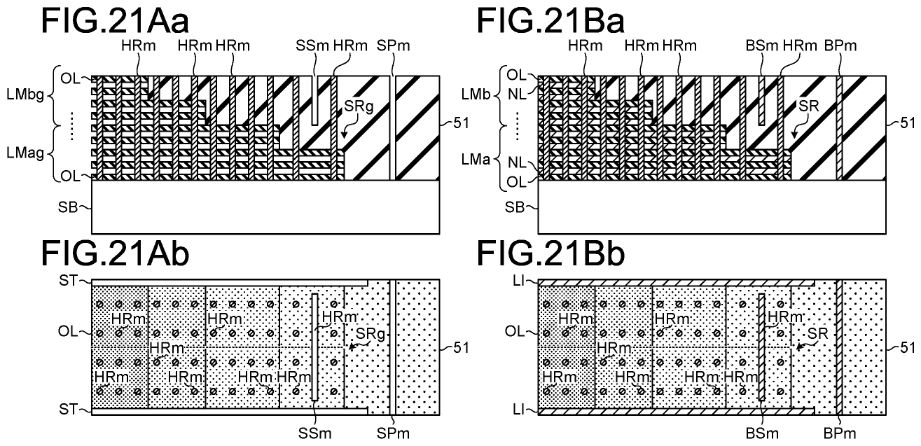

As illustrated in FIGS. 21Aa and 21Ab, the sacrificial layer NL of the stacked bodies LMas and LMbs is removed through the slit ST to form the stacked bodies LMag and LMbg having a gap between the insulating layers OL.

At this time, the columnar bodies HRm filled with each of the above layers support the stacked bodies LMag and LMbg in the stepped region SRg, and the pillars PL support the stacked bodies LMag and LMbg in the memory region MR (not illustrated). In addition, the slits SSm and SPm mitigate the compressive stress from the insulating layer 51 to the stacked bodies LMag and LMbg and the stepped region SRg.

As illustrated in FIGS. 21Ba and 21Bb, the gap between the insulating layers OL of the stacked bodies LMag and LMbg is filled with a conductive material through the slit ST to form the word line WL.

Incidentally, before forming the word line WL, a metal element-containing block layer such as an Al₂O₃ layer and a barrier metal layer such as a TiN layer may be formed on upper and lower surfaces and an end portion close to the slit ST of the insulating layer OL in the order of proximity to the insulating layer OL. These metal element-containing block layer and barrier metal layer may be formed on end surfaces of the insulating layer 51 close to the slits ST, SSm, and SPm. Between the metal element-containing block layer and the barrier metal layer, the barrier metal layer is removed from the slits ST, SSm, and SPm when the word line WL is formed.

After the formation of the word line WL, the insulating layer and the like are collectively formed on side walls of the respective slits ST, SSm, and SPm, and the inside of the insulating layer is filled collectively with, for example, a filling layer, such as a tungsten layer, and the like. As a result, the contact LI and the split bands BSm and BPm are formed, respectively.

Thereafter, the contact CC, which penetrates the insulating layer 51 above the stepped region SR and the insulating layer OL on the terrace surface in each step of the stepped region SR and reaches the word line WL on the lower layer, is formed. At this time, the inclination of the columnar body HR is suppressed by the stress suppressing effect of the split bands BSm and BPm, and the contact between the columnar body HR and the contact CC is suppressed.

In addition, the insulating member SHE, which splits the conductive layer above the word line WL on the uppermost layer, is formed on the stacked bodies LMa and LMb in the memory region MR. In addition, an upper layer wiring connected to the contacts CC and LI, the channel layer CN of the pillar PL, and the like is formed.

As described above, the semiconductor storage device 40 of the fourth embodiment is manufactured.

According to the semiconductor storage device 40 of the fourth embodiment, the pillar PL, the columnar body HRm, and the split bands BSm and BPm are formed in parallel.

That is, the memory hole, the hole HLa, and the slit SHb (borrowed from FIGS. 10Aa and 10Ab) are collectively formed in the stacked body LMas, and further, these memory hole, hole HLa, and slit SHb are collectively filled with sacrificial layers such as amorphous silicon layers.

In addition, the memory hole, the hole HLb, and the slits SSm and SPmt are collectively formed in the stacked body LMbs, and the sacrificial layers are collectively removed from the memory hole, the columnar body HRs, and the split band BPms in the stacked body LMas through these memory hole, hole HLb, and slit SPmt.

In addition, the respective layers in the memory hole and the hole HL of the stacked bodies LMas and LMbs are collectively formed, and the pillar PL and the columnar body HRm are formed, respectively.

As a result, a manufacturing process of the semiconductor storage device 40 can be shortened, and the cost can be reduced.

Incidentally, for example, a plurality of the split bands BPm may be arranged outside the stepped region SR in the fourth embodiment as well. In addition, a plurality of the split bands BSm may be arranged close to each other at the time of arranging the split band BSm in the stepped region SR.

In addition, the slit ST may be filled with a conductive layer such as a polysilicon layer, instead of or in addition to the tungsten layer, in the fourth embodiment as well. In addition, the slit ST may be filled with an insulating layer such as a SiO₂ layer, instead of the conductive layer.

Along with the above configuration, the slits SSm and SPm may also be filled with a conductive layer or an insulating layer similarly to the slit ST.

In addition, in the fourth embodiment described above, the slits SSm and SPm are formed, and the filling layer is formed in the slits SSm and SPm to form, for example, the split bands BSm and BPm continuous in a band shape. However, instead of the slits SSm and SPm, a plurality of holes arrayed in the Y direction may be formed, and filling layers may be formed in these holes to form the split bands BSm and BPm having a plurality of columnar portions, for example.

In this case, the plurality of holes has shapes similar to those of the memory holes, it becomes easier to collectively form these holes and memory holes. However, it suffices that the slits SSm and SPm and the split bands BSm and BPm continuous in a band shape have a stress adjusting function, and the processing accuracy required for these configurations is not so high.

### Other Embodiments

In the above-described first to fourth embodiments, the split bands BPs, BHs, BPp, BHp, and BPm are arranged near the terminal end portion of the contact LI in the X direction. However, the split bands BPs, BHs, BPp, BHp, and BPm may be arranged outside the stepped region SR in a region sandwiched between the two contacts LI.

In the above-described first to fourth embodiments, the stacked bodies LMa and LMb are arranged on the substrate SB such as a silicon substrate, and the peripheral circuit is arranged outside the stacked bodies LMa and LMb in the semiconductor storage device. However, the stacked bodies LMa and LMb may be arranged, for example, above the peripheral circuit via a source line or the like. Alternatively, the peripheral circuit may be arranged above the stacked bodies LMa and LMb. Such a configuration can be obtained, for example, by inverting and bonding the stacked bodies LMa and LMb to a substrate on which the peripheral circuit has been arranged.

In the above-described first to fourth embodiments, the semiconductor storage device has a two-tier structure including the stacked bodies LMa and LMb stacked in two hierarchies. However, the semiconductor storage device may have a one-tier structure including a stacked body in one hierarchy, or may have a three-tier or higher structure including stacked bodies in three or more hierarchies.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A semiconductor storage device comprising:
a stacked body in which a plurality of first conductive layers is stacked with a first insulating layer interposed between the plurality of first conductive layers, the stacked body having a stepped region in which end portions of the plurality of first conductive layers are terminated in a stepped shape and a memory region in which a plurality of memory cells is arranged;
a second insulating layer that covers the stepped region and reaches at least a height of an upper surface of the stacked body in the memory region; and
a first structure having a longitudinal direction along a first direction that intersects an ascending/descending direction of the stepped region, the first structure extending in a stacking direction of the stacked body in the second insulating layer, the first structure interrupting spread of the second insulating layer on the stepped region in a second direction along the ascending/descending direction.

2. The semiconductor storage device according to claim 1, further comprising:
a second structure having a longitudinal direction along the first direction and extending in a thickness direction of the second insulating layer, the second insulating layer also spreading outside the stepped region, and the second structure substantially penetrating the second insulating layer outside the stepped region.

3. The semiconductor storage device according to claim 2, wherein
a width of the second structure in the second direction is wider than a width of the first structure in the second direction.

4. The semiconductor storage device according to claim 2, wherein
an aspect ratio of the first structure is higher than an aspect ratio of the second structure.

5. The semiconductor storage device according to claim 1, wherein
the first structure includes a plurality of first structures arranged in the second direction.

6. The semiconductor storage device according to claim 1, wherein
the first structure has a lower end portion located in the second insulating layer and above the stacked body in the stepped region.

7. The semiconductor storage device according to claim 1, wherein
the first structure extends continuously in the first direction.

8. The semiconductor storage device according to claim 1, wherein
the first structure includes a plurality of columnar portions arrayed in the first direction.

9. The semiconductor storage device according to claim 1, wherein
the first structure contains a material having tensile stress.

10. The semiconductor storage device according to claim 1, wherein
the first structure contains tungsten, polysilicon, or SiO₂ .

11. The semiconductor storage device according to claim 2, wherein
the first structure contains a first material, and
the second structure contains the first material in an upper portion and contains a second material, which has tensile stress and is different from the first material, in a lower portion.

12. The semiconductor storage device according to claim 11, wherein
the first material has tensile stress, and the second material has higher tensile stress than the first material.

13. The semiconductor storage device according to claim 11, wherein
the first material is a conductive material or an insulating material, and
the second material is a semiconductor material.

14. The semiconductor storage device according to claim 11, wherein
the first material is tungsten, polysilicon, or SiO₂, and
the second material is amorphous silicon.

15. A semiconductor storage device comprising:
a stacked body in which a plurality of first conductive layers is stacked with a first insulating layer interposed between the plurality of first conductive layers, the stacked body having a stepped region in which end portions of the plurality of first conductive layers are terminated in a stepped shape and a memory region in which a plurality of memory cells is arranged;
a second insulating layer that covers the stepped region and spreads toward an outside of the stepped region, and reaches at least a height of an upper surface of the stacked body in the memory region;
a structural portion having a longitudinal direction along a first direction that intersects an ascending/descending direction of the stepped region, the structural portion extending in a thickness direction of the second insulating layer, the structural portion interrupting spread of the second insulating layer outside the stepped region in a second direction along the ascending/descending direction; and
a split portion having a longitudinal direction along the second direction, extending in a stacking direction of the stacked body, and splitting the stacked body in the first direction, wherein
the split portion contains a first material, and
the structural portion
contains the first material in an upper portion and
contains a second material, which has tensile stress and is different from the first material, in a lower portion.

16. The semiconductor storage device according to claim 15, wherein
the first material is a conductive material or an insulating material, and
the second material is a semiconductor material.

17. The semiconductor storage device according to claim 15, wherein
the first material is tungsten, polysilicon, or SiO₂, and
the second material is amorphous silicon.

18. The semiconductor storage device according to claim 15, wherein
the structural portion extends continuously in the first direction.

19. The semiconductor storage device according to claim 15, wherein
the structural portion includes a plurality of columnar portions arrayed in the first direction.

20. The semiconductor storage device according to claim 15, wherein
an aspect ratio of the split portion is equal to or lower than an aspect ratio of the upper portion of the structural portion.
